(19) United States
(12) Patent Application Publication
(10) Pub. No.: US 2022/0285918 A1
(43) Pub. Date: Sep. 8, 2022

(54) SEMICONDUCTOR LIGHT-EMITTING ELEMENT AND METHOD OF MANUFACTURING THE SAME

(71) Applicant: Nuvoton Technology Corporation Japan, Kyoto (JP)

(72) Inventors: Toru TAKAYAMA, Toyama (JP); Takashi YUMOTO, Toyama (JP); Takeshi YOKOYAMA, Toyama (JP); Tougo NAKATANI, Toyama (JP); Shoichi TAKASUKA, Toyama (JP)

(21) Appl. No.: 17/745,229

(22) Filed: May 16, 2022

Related U.S. Application Data
(63) Continuation of application No. PCT/JP2020/044067, filed on Nov. 26, 2020.

(30) Foreign Application Priority Data
Nov. 27, 2019 (JP) 2019-213817

(51) Int. Cl. H01S 5/343

(52) U.S. Cl. CPC H01S 5/34366; H01S 5/34313

(57) ABSTRACT

A semiconductor light-emitting element includes: a substrate; an n-type clad layer above the substrate; an active layer above the n-type clad layer; and a p-type clad layer above the active layer. The active layer includes: a well layer; an n-side first barrier layer on an n-type clad layer side of the well layer; and a p-side barrier layer on a p-type clad layer side of the well layer. The p-side barrier layer comprises In. The n-side first barrier layer has an In composition ratio lower than an In composition ratio of the p-side barrier layer. The n-side first barrier layer has a band gap energy smaller than a band gap energy of the p-side barrier layer.

### CROSS REFERENCE TO RELATED APPLICATION

This is a continuation application of PCT International Application No. PCT/JP2020/044067 filed on Nov. 26, 2020, designating the United States of America, which is based on and claims priority of Japanese Patent Application No. 2019-213817 filed on Nov. 27, 2019. The entire disclosures of the above-identified applications, including the specifications, drawings and claims are incorporated herein by reference in their entirety.

### FIELD

The present disclosure relates to a semiconductor light-emitting element, and particularly to a semiconductor light-emitting element including an active layer having a quantum well structure.

### BACKGROUND

Conventionally, laser light has been used for processing, and there has been a need for a high-output and high-efficient laser light source. A semiconductor light-emitting element such as a semiconductor laser element has been used as such a laser light source. There has been a demand for a higher-output laser light source, especially for use in welding among processing.

Patent Literature (PTL) 1 discloses an example of a technique for achieving a higher-output semiconductor light-emitting element. PTL 1 discloses a technique for decreasing energy difference δEv between a first quantum level of heavy holes in a well layer and an energy level of a barrier layer at the top of a valence band, and increasing energy difference δEc between a first quantum level of electrons in the well layer and an energy level of the barrier layer at the bottom of a conduction band, in an active layer having a quantum well structure. The semiconductor light-emitting element described in PTL 1 intends to control electron overflow (i.e., leak) from the well layer by increasing energy difference δEc while intending to increase a probability of recombination of holes and electrons by decreasing energy difference δEv to improve the movability of the holes.

### CITATION LIST

### Patent Literature

PTL 1: Japanese Unexamined Patent Application Publication No. 10-256659

### SUMMARY

### Technical Problem

In the semiconductor light-emitting element described in PTL 1, however, since energy difference δEc is large, an operating voltage necessary for injecting electrons into the well layer increases. Concomitantly, since the self-heating of the semiconductor light-emitting element increases, a thermal saturation level is reduced.

The present disclosure is intended to solve such a problem, and has an object to provide, for example, a semiconductor light-emitting element that is capable of controlling electron overflow from a well layer while suppressing an operating voltage.

### Solution to Problem

In order to solve the above problem, a semiconductor light-emitting element according to one aspect of the present disclosure includes: a substrate; an n-type clad layer above the substrate; an active layer above the n-type clad layer; and a p-type clad layer above the active layer. The active layer includes: a well layer; an n-side first barrier layer on an n-type clad layer side of the well layer; and a p-side barrier layer on a p-type clad layer side of the well layer. The p-side barrier layer comprises In. The n-side first barrier layer has an In composition ratio lower than an In composition ratio of the p-side barrier layer. The n-side first barrier layer has a band gap energy smaller than a band gap energy of the p-side barrier layer.

As stated above, the In composition ratio of the n-side first barrier layer is made lower than the In composition ratio of the p-side barrier layer, and the band gap energy of the n-side first barrier layer is made smaller than the band gap energy of the p-side barrier layer. Consequently, it is possible to make energy difference ΔEc between the conduction potential energies of the p-side barrier layer and the n-side first barrier layer larger than energy difference ΔEv between the valance band potential energies of the p-side barrier layer and the n-side first barrier layer. Accordingly, it is possible to control electron overflow from the well layer while suppressing an increase in voltage necessary for electrical conduction of holes, that is, an increase in operating voltage of the semiconductor light-emitting element.

In the semiconductor light-emitting element according to the one aspect of the present disclosure, a composition of the n-side first barrier layer may be represented by Al_{ybn1}Ga_{1-xbn1-ybn1}In_{xbn1}As, a composition of the p-side barrier layer may be represented by Al_{ybp1}Ga_{1-xbp1-ybp1}In_{xbp1}As, and 0≤ybn1≤1, 0≤xbn1≤1, 0<ybp1<1, 0<xbp1<1, and xbn1<xbp1 may be satisfied.

By using the n-side first barrier layer and the p-side barrier layer having such compositions, it is possible to make the In composition ratio of the n-side first barrier layer lower than the In composition ratio of the p-side barrier layer, and the band gap energy of the n-side first barrier layer smaller than the band gap energy of the p-side barrier layer.

In the semiconductor light-emitting element according to the one aspect of the present disclosure, ybn1<ybp1 may be further satisfied.

Accordingly, since energy difference ΔEc between the conduction band potential energies of the p-side barrier layer and the n-side first barrier layer increases, it is possible to further control the electron overflow from well layer.

In the semiconductor light-emitting element according to the one aspect of the present disclosure, 0.2≤ybn1≤0.4, ybp1≤xbp1+0.975ybn1+0.069, ybp1≤0.4xbp1+0.975ybn1+0.029, and xbp1≤0.15 may be further satisfied.

By causing Al composition ratio ybn1 of the n-side first barrier layer to be at least 0.2 and at most 0.4, it is possible to reduce a loss in a waveguide while suppressing a significant decrease in light confinement factor for confining light to the well layer.

Moreover, since the above relations are satisfied with regard to Al composition ratio ybp1 of the p-side barrier layer, it is possible to increase energy difference ΔEc2 between conduction band potential energies of the n-side first barrier layer and the p-side barrier layer to at least 25 meV while reducing energy difference ΔEv2 between valance band potential energies of the n-side first barrier layer and the p-side barrier layer to at most 30 meV. Accordingly, it is possible to suppress an increase in operating voltage by reducing energy difference ΔEv2, and control the electron overflow by increasing energy difference ΔEc2.

Furthermore, by causing Al composition ratio xbp1 of the p-side barrier layer to be at most 0.15, it is possible to reduce a lattice misfit between the GaAs substrate and the p-side barrier layer to 1.2% at a maximum.

The semiconductor light-emitting element according to the one aspect of the present disclosure may further include a p-side intermediate layer between the well layer and the p-side barrier layer. A composition of the p-side intermediate layer may be represented by Al_{ykp1}Ga_{1-ykp1}As, and ybp1≤xbp1+0.975ykp1+0.069, ybp1≤0.4xbp1+0.975ykp1+0.029, and 0.2≤ykp1≤0.4 may be satisfied.

When the above relations are satisfied with regard to Al composition ratio ybp1 of the p-side barrier layer, energy difference ΔEc2 between conduction band potential energies of the n-side first barrier layer and the p-side barrier layer is at least 25 meV, and energy difference ΔEv2 between valance band potential energies of the n-side first barrier layer and the p-side barrier layer is at most 30 meV. Accordingly, since it is possible to reduce prevention of holes from being injected into well layer 14d, it is possible to suppress an increase in operating voltage. In addition, it is possible to control the electron overflow from well layer.

Moreover, by causing the Al composition ratio of the p-side intermediate layer to be at least 0.2 and at most 0.4, it is possible to further highly accurately control a vertical light distribution and to reduce the loss in the waveguide while increasing the light confinement factor.

Furthermore, since it is possible to disperse compression strain forming regions in the vicinity of the active layer by disposing, between the well layer and the p-side barrier layer that includes the AlGaAs layer substantially lattice-matched with the GaAs substrate, it is possible to suppress a decrease in crystallinity due to the concentration of the compression strain.

Additionally, since it is possible to reduce energy difference ΔEv between valance potential energies of the well layer and the p-side intermediate layer, it is possible to suppress formation of light holes having high-order levels. Accordingly, it is possible to suppress the reduction of a polarization ratio.

The semiconductor light-emitting element according to the one aspect of the present disclosure may further include an n-side second barrier layer between the n-side first barrier layer and the well layer. A composition of the n-side second barrier layer may be represented by Al_{ybn2}Ga_{1-xbn2-ybn2}In_{xbn2}As, and ybn2≥xbn2+ybn1, ybn2≤0.4xbn2+0.975ybn1+0.061, xbn2≤0.15, and 0.2≤ybn1≤0.35 may be satisfied.

When the above relations are satisfied with regard to Al composition ratio ybn2 of the n-side second barrier layer, energy difference ΔEc2 between conduction band potential energies of the n-side first barrier layer and the n-side second barrier layer is at most 50 meV, and energy difference ΔEv2 between valance band potential energies of the n-side first barrier layer and the n-side second barrier layer is at least 30 meV. Accordingly, since it is possible to reduce prevention of holes from being injected into the well layer, it is possible to suppress an increase in operating voltage. In addition, it is possible to control hole overflow from the well layer.

Moreover, since it is possible to increase a refractive index of the n-side first barrier layer by causing the Al composition ratio of the n-side first barrier layer to be at least 0.2 and at most 0.35, the vertical light distribution is easily skewed toward an n-type semiconductor layer side. Accordingly, it is possible to reduce the loss in the waveguide.

The semiconductor light-emitting element according to the one aspect of the present disclosure may further include an n-side third barrier layer between the well layer and the n-side second barrier layer. A composition of the n-side third barrier layer may be represented by Al_{ybn3}Ga_{1-ybn3}As, and ybn2≥xbn2+ybn3, ybn2≤0.4xbn2+0.975ybn3+0.061, and 0.2≤ybn3≤0.35 may be satisfied.

When the above relations are satisfied with regard to Al composition ratio ybn2 of the n-side second barrier layer, energy difference ΔEc2 between conduction band potential energies of the n-side second barrier layer and the n-side third barrier layer is at most 50 meV. In addition, by causing the Al composition ratio of the n-side third barrier layer to be at most 0.35, it is possible to reduce a band gap energy of the n-side third barrier layer. Accordingly, since it is possible to reduce prevention of electrons from being injected into the well layer, it is possible to suppress an increase in operating voltage.

Moreover, when the above relations are satisfied with regard to Al composition ratio ybn2 of the n-side second barrier layer, energy difference ΔEv2 between valance band potential energies of the n-side second barrier layer and the n-side third barrier layer is at least 0 meV. In consequence, it is possible to control hole overflow from the well layer.

Furthermore, since it is possible to increase a refractive index of the n-side third barrier layer by causing the Al composition ratio of the n-side third barrier layer to be at least 0.2 and at most 0.35, a vertical light distribution is easily skewed toward the n-type semiconductor layer side. Accordingly, it is possible to reduce the loss in the waveguide.

The semiconductor light-emitting element according to the one aspect of the present disclosure may further include a p-side guide layer between the p-side barrier layer and the p-type clad layer, the p-side guide layer having a refractive index higher than a refractive index of the p-type clad layer.

Since the semiconductor light-emitting element includes, on the p-side barrier layer, the p-side guide layer having the higher refractive index than the p-type clad layer, it is possible to highly accurately control a vertical light distribution and suppress an excessive skew of the light distribution toward the n-type semiconductor layer side. Accordingly, the semiconductor light-emitting element makes it possible to suppress a decrease in light confinement factor for confining light to the well layer in the vertical direction, and an increase in operating carrier density in the well layer. In other words, the semiconductor light-emitting element makes it possible to suppress a deterioration of temperature characteristics of the semiconductor light-emitting element. Additionally, since the semiconductor light-emitting element makes it possible to suppress an increase in free carrier loss due to impurity doping when the p-side guide layer is undoped, the semiconductor light-emitting element makes it possible to reduce a loss in a waveguide. As a result, it is possible to achieve a semiconductor laser element having excellent temperature characteristics and a high slope efficiency.

In the semiconductor light-emitting element according to the one aspect of the present disclosure, a composition of the p-side guide layer may be represented by Al_{ygp1}Ga_{1-ygp1}As, and ybp1≤xbp1+0.975ygp1+0.069, ybp1≥0.4xbp1+0.975ygp1+0.029, and 0.2≤ygp1≤0.4 may be satisfied.

The p-side guide layer having such a composition is substantially lattice-matched with the GaAs substrate. For this reason, it is possible to cause a thickness of the p-side barrier layer having a compressive lattice misfit to be less than or equal to a critical thickness. Accordingly, it is possible to suppress a decrease in crystallinity of the p-side barrier layer.

When the well layer is a quaternary semiconductor material film containing Al, the compression strain of the active layer increases. For this reason, it is possible to suppress an accumulation of compression strain in the vicinity of the active layer by disposing the p-side guide layer substantially lattice-matched with the GaAs substrate above the p-side barrier layer. Furthermore, in this case, since potential energy between the ground levels for heavy holes and light holes increases, it is possible to reduce a probability of recombination between light holes and electrons. Accordingly, since it is possible to decrease the intensity of TM polarized light due to the recombination between the light holes and the electrons, the polarization ratio increases.

Since the above relations are satisfied, it is possible to cause energy difference ΔEc2 between the conduction band potential energies of the p-side barrier layer and the p-side guide layer to be at least 25 meV while causing energy difference ΔEc2 between the valance band potential energies of the p-side barrier layer and the p-side guide layer to be at most 30 meV. Consequently, it is possible to control the electron overflow from the well layer while suppressing an increase in operating voltage.

Additionally, by causing Al composition ratio ygp1 of the p-side guide layer to be at least 0.2 and at most 0.4, it is possible to further highly accurately control the vertical light distribution and to reduce the loss in the waveguide while suppressing a significant decrease in light confinement factor.

In the semiconductor light-emitting element according to the one aspect of the present disclosure, a composition of the p-side guide layer may be represented by (Al_{ygp2}Ga_{1-ygp2})_{0.5}In_{0.5}P.

For this reason, vacancies or impurities such as Zn and Mg are easily diffused in the p-side guide layer. Accordingly, it is possible to reduce the time needed to form a window mirror structure by diffusing vacancies or impurities into the semiconductor light-emitting element. Moreover, since it is possible to decrease an impurity concentration used when the impurities are diffused, it is possible to reduce the light absorption by the impurities. Consequently, it is possible to suppress a decrease in luminous efficiency of the semiconductor light-emitting element.

In the semiconductor light-emitting element according to the one aspect of the present disclosure, a composition of the n-type clad layer may be represented by Al_{yn1}Ga_{1-yn1}As, a composition of the p-type clad layer may be represented by Al_{yp1}Ga_{1-yp1}As, and 0<yn1<yp1<1 may be satisfied.

Since the Al composition ratio of the n-type clad layer is lower than the Al composition ratio of the p-type clad layer as above, the n-type clad layer has a higher refractive index than the p-type clad layer does. Concomitantly, the vertical light distribution is skewed toward the n-type clad layer side. As stated above, since the free carrier loss of the light in the waveguide of the semiconductor light-emitting element is greater in the p-type semiconductor layer having a higher doping concentration than the n-type semiconductor layer does, it is possible to reduce the waveguide loss by skewing the vertical light distribution toward the n-type semiconductor layer.

Since the skew of the light distribution toward the n-type clad layer side causes a decrease in light confinement factor in the vertical direction relative to the well layer that is an emission layer, as stated above, the electrons easily overflow from the well layer to the p-side barrier layer. In the semiconductor light-emitting element according to the present embodiment, however, since energy difference ΔEc between the conduction band potential energies of the p-side barrier layer and the n-side first barrier layer is large, it is possible to control the electron overflow. Accordingly, it is possible to achieve a semiconductor light-emitting element that is capable of improving temperature characteristics more greatly than the conventional semiconductor light-emitting elements while suppressing the increase in operating voltage, has a high slope efficiency, and operates with a low operating current.

In the semiconductor light-emitting element according to the one aspect of the present disclosure, a composition of the n-type clad layer may be represented by (Al_{yn2}Ga_{1-yn2})_{0.5}In_{0.5}P, a composition of the p-type clad layer may be represented by (Al_{yp2}Ga_{1-yp2})_{0.5}In_{0.5}P, and 0<yn2<yp2<1 may be satisfied.

Since the semiconductor light-emitting element includes the n-type clad layer and the p-type clad layer having such compositions, vacancies or impurities such as Zn and Mg are easily diffused in the n-type clad layer and the p-type clad layer. Accordingly, it is possible to reduce the time needed to form a window mirror structure by diffusing vacancies or impurities into the semiconductor light-emitting element. Moreover, since it is possible to decrease an impurity concentration used when the impurities are diffused, it is possible to reduce the light absorption by the impurities. Consequently, it is possible to suppress a decrease in luminous efficiency of the semiconductor light-emitting element.

Furthermore, since 0<yn2<yp2<1 is satisfied, it is possible to make a refractive index of the p-type clad layer lower that a refractive index of the n-type clad layer. For this reason, it is possible to skew a laser light intensity distribution toward the n-type clad layer side. In other words, since it is possible to reduce laser light propagating through the p-type clad layer, it is possible to reduce a free carrier loss due to the impurities in the p-type clad layer. Accordingly, it is possible to reduce a loss in a waveguide.

In the semiconductor light-emitting element according to the one aspect of the present disclosure, a composition of the well layer may be represented by Al_{yw}Ga_{1-xw-yw}In_{xw}As, and 0≤yw<1 and 0<xw<1 may be satisfied.

When the composition of the well layer is Al_{yw}Ga_{1-xw-yw}In_{xw}As as above, it is possible to adjust the magnitude of a strain in the well layer and a conduction band potential energy difference and a valance band potential energy difference between the well layer and each barrier layer, by adjusting the Al composition ratio, Ga composition ratio, and In composition ratio of the well layer. Accordingly, it is possible to adjust an oscillation wavelength of the semiconductor light-emitting element and control the electron overflow from the well layer.

In the semiconductor light-emitting element according to the one aspect of the present disclosure, 0<yw<1 may be further satisfied.

In this way, when the well layer has a compression strain because the well layer contains Al, it is possible to decrease the number of light holes formed in a valance band of the well layer. Here, light generated by recombining light holes (LH) and electrons has a higher ratio of TM mode light than light generated by recombining heavy holes (HH) and electrons. As a result, since it is possible to reduce the probability of recombination between the light holes and the electrons by decreasing the number of the light holes formed in the valance band of the well layer, it is possible to increase the polarization ratio (an intensity ratio of TE mode light to TM mode light) of the light outputted from the semiconductor light-emitting element.

In the semiconductor light-emitting element according to the one aspect of the present disclosure, the substrate may be a GaAs substrate.

As stated above, when an AlGaInAs-based quaternary semiconductor material is used for the barrier layer and the well layer, using the GaAs substrate as the substrate makes it possible to cause a compression strain in the well layer. When the well layer has a compression strain, it is possible to decrease the number of light holes formed in the valance band of the well layer, by adjusting the composition of the well layer. Consequently, since it is possible to reduce the probability of recombination between the light holes and the electrons, it is possible to increase a polarization ratio of light outputted from the semiconductor light-emitting element.

In the semiconductor light-emitting element according to the one aspect of the present disclosure, the n-type clad layer may have a band gap energy smaller than a band gap energy of the p-type clad layer.

As a result, the n-type clad layer has a higher refractive index than the p-type clad layer does. For this reason, a light distribution in a direction vertical to a principal surface of the substrate is skewed toward the n-type clad layer side. Here, in an n-type semiconductor layer, it is possible to reduce a resistance value by causing a doping concentration of n-type impurities to be in a range from 1×10¹⁶ cm⁻³ to 1×10¹⁸ cm⁻³. On the other hand, in a p-type semiconductor layer, it is not possible to reduce a resistance value if a doping concentration of p-type impurities is not caused to be at least 1×10¹⁸ cm⁻³. Consequently, a free carrier loss of light in the waveguide of the semiconductor light-emitting element is greater in the p-type semiconductor layer having a higher doping concentration than the n-type semiconductor layer does. Accordingly, it is possible to reduce a waveguide loss by skewing a light distribution toward the n-type clad layer side as in the semiconductor light-emitting element according to the present embodiment.

The skew of the light distribution toward the n-type clad layer side causes a decrease in light confinement factor in the vertical direction (in the direction vertical to the principal surface of the substrate) relative to the well layer that is an emission layer. For this reason, when the semiconductor light-emitting element performs laser oscillation, the number of operating carriers easily increases in the well layer, and electrons having a smaller effective mass than holes easily overflow from the well layer to the p-side barrier layer. In the semiconductor light-emitting element according to the present embodiment, however, since energy difference ΔEc between the conduction band potential energies of the p-side barrier layer and the n-side first barrier layer is large, it is possible to control the electron overflow. Accordingly, it is possible to achieve a semiconductor light-emitting element that is capable of improving temperature characteristics more greatly than the conventional semiconductor light-emitting elements while suppressing the increase in operating voltage, has a high slope efficiency, and operates with a low operating current.

In the semiconductor light-emitting element according to the one aspect of the present disclosure, a light-emitting end face portion of the active layer may have a window mirror structure.

Among AlAs, GaAs, and InAs, InAs has the largest lattice constant and the smallest band gap energy. As with the semiconductor light-emitting element according to the present variation, when a desired band gap energy is obtained by using an AlGaInAs-based quaternary semiconductor material for the well layer and each barrier layer, an In content rate of the well layer including AlGaInAs increases, which increases a compression strain of the well layer, compared to when a desired band gap energy is obtained by using a semiconductor material including InGaAs for the well layer.

It should be noted that when a nitride-based semiconductor material is used, among AlN, GaN, and InN, InN has the largest lattice constant and the smallest band gap energy. In this case, when a desired band gap energy is obtained by using a layer including a quaternary-based semiconductor material including AlGaInN for a well layer and each barrier layer, the In content rate of the well layer including AlGaInN increases, which increases a compression strain of the well layer, compared to when a desired band gap energy is obtained by using a semiconductor material including InGaN or AlGaN for the well layer.

As seen from the above, when vacancies or impurities are diffused into the light-emitting end face portion of the semiconductor light-emitting element in a structure in which AlGaInAs, AlGaInN, or the like is used for the well layer and each barrier layer, since a strain energy of the well layer is reduced, the In atoms of the well layer are easily exchanged with the Al atoms and Ga atoms in group-III lattice positions relative to the stacked direction. Accordingly, a band gap energy of the well layer easily increases.

As a result, the band gap energy of the well layer increases in the light-emitting end face portion having a high light density, and it is possible to form what is called a window structure. For this reason, even when a band gap energy of the light-emitting end face portion is reduced due to heat generation, it is possible to maintain the light absorption by the light-emitting end face portion in the well layer at a low level. Accordingly, it is possible to suppress the occurrence of catastrophic optical damage (COD) due to the light absorption by the light-emitting end face portion.

Additionally, when the window structure is formed by vacancy diffusion, it is possible to suppress the occurrence of a free carrier loss due to the presence of impurities, and thus it is possible to suppress a decrease in slope efficiency, compared to a case in which the window structure is formed by impurity diffusion.

In the semiconductor light-emitting element according to the one aspect of the present disclosure, a portion of the active layer that has the window mirror structure may have a band gap energy larger than a band gap energy of a portion of the active layer that does not have the window mirror structure.

For this reason, even when a band gap energy of the light-emitting end face portion is reduced due to heat generation, it is possible to maintain the light absorption by the light-emitting end face portion in the well layer at a low level. Accordingly, it is possible to suppress the occurrence of COD due to the light absorption by the light-emitting end face portion.

In order to solve the above-described problem, a method of manufacturing a semiconductor light-emitting element according to one aspect of the present disclosure includes: preparing a substrate; forming an n-type clad layer above the substrate; forming an active layer above the n-type clad layer; forming a p-type clad layer above the active layer; and forming a window mirror structure in the active layer. The active layer includes: a well layer; an n-side first barrier layer on an n-type clad layer side of the well layer; and a p-side barrier layer on a p-type clad layer side of the well layer. The p-side barrier layer comprises In. The n-side first barrier layer has an In composition ratio lower than an In composition ratio of the p-side barrier layer. The n-side first barrier layer has a band gap energy smaller than a band gap energy of the p-side barrier layer. In the forming of the window mirror structure, vacancies or impurities are diffused into the active layer.

As a result, it is possible to manufacture a semiconductor light-emitting element in which the In composition ratio of the n-side first barrier layer is made lower than the In composition ratio of the p-side barrier layer, and the band gap energy of the n-side first barrier layer is made smaller than the band gap energy of the p-side barrier layer. Such a semiconductor light-emitting element makes it possible to cause energy difference ΔEc between the conduction potential energies of the p-side barrier layer and the n-side first barrier layer to be larger than energy difference ΔEv between the valance band potential energies of the p-side barrier layer and the n-side first barrier layer. Accordingly, it is possible to control electron overflow from the well layer while suppressing an increase in voltage necessary for electrical conduction of holes, that is, an increase in operating voltage of the semiconductor light-emitting element.

Moreover, for example, when vacancies or impurities are diffused into a light-emitting end face portion of the semiconductor light-emitting element in a structure in which AlGaInAs, AlGaInN, or the like is used for the well layer and each barrier layer, since a strain energy of the well layer is reduced, the In atoms of the well layer are easily exchanged with the Al atoms and Ga atoms in group-III lattice positions relative to the stacked direction. Accordingly, a band gap energy of the well layer easily increases.

As a result, the band gap energy of the well layer increases in the light-emitting end face portion having a high light density, and it is possible to form what is called a window structure. For this reason, even when a band gap energy of the light-emitting end face portion is reduced due to heat generation, it is possible to maintain the light absorption by the light-emitting end face portion in the well layer at a low level. Accordingly, it is possible to suppress the occurrence of COD due to the light absorption by the light-emitting end face portion.

### Advantageous Effects

The present disclosure provides, for example, a semiconductor light-emitting element capable of controlling electron overflow from a well layer while suppressing an operating voltage.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view schematically illustrating an entire configuration of a semiconductor light-emitting element according to Embodiment 1.

FIG. 2 is a cross-sectional view schematically illustrating a detailed configuration of an active layer included in the semiconductor light-emitting element according to Embodiment 1.

FIG. 3 is a schematic diagram illustrating an outline of an energy band structure of an active layer according to a comparative example.

FIG. 4 is a schematic diagram illustrating an outline of an energy band structure of the active layer according to Embodiment 1.

FIG. 5 is a schematic diagram illustrating an energy difference between conduction band potential energies of an n-side first barrier layer and a p-side barrier layer of the active layer according to Embodiment 1, and an energy difference between valence band potential energies of the n-side first barrier and the p-side barrier layer.

FIG. 6 is a graph showing In and Al composition ratio dependence of band gap energy (Eg) of an AlGaInAs-based material.

FIG. 7 is a graph showing In and Al composition ratio dependence of valence band potential energy of an AlGaInAs-based material.

FIG. 8 is a graph showing In and Al composition ratio dependence of conduction band potential energy of an AlGaInAs-based material.

FIG. 9 is a graph showing relations between energy difference ΔEc2 between conduction band potential energies of an AlGaInAs-based material and Al_{0.2}Ga_{0.7}As, energy difference ΔEv2 between valence band potential energies of the AlGaInAs-based material and Al_{0.2}Ga_{0.7}As, and the composition of the AlGaInAs-based material.

FIG. 10 is a graph showing relations between energy difference ΔEc2 between conduction band potential energies of an AlGaInAs-based material and Al_{0.3}Ga_{0.7}As, energy difference ΔEv2 between valence band potential energies of the AlGaInAs-based material and Al_{0.3}Ga_{0.7}As, and the composition of the AlGaInAs-based material.

FIG. 11 is a graph showing relations between energy difference ΔEc2 between conduction band potential energies of an AlGaInAs-based material and Al_{0.4}Ga_{0.6}As, energy difference ΔEv2 between valence band potential energies of the AlGaInAs-based material and Al_{0.4}Ga_{0.6}As, and the composition of the AlGaInAs-based material.

FIG. 12 is a graph showing simulation results of current-voltage characteristics of a semiconductor light-emitting element according to Comparative Example 1.

FIG. 13 is a graph showing simulation results of current-voltage characteristics of a semiconductor light-emitting element according to Comparative Example 2.

FIG. 14 is a graph showing simulation results of current-voltage characteristics of the semiconductor light-emitting element according to Embodiment 1.

FIG. 15 is a graph showing a relation between an Al composition ratio and an operating voltage of a quaternary barrier layer of each of the semiconductor light-emitting elements according to Comparative Example 1, Comparative Example 2, and Embodiment 1.

FIG. 16 is a first graph showing calculation results of a relation between (i) an Al composition ratio of the well layer according to Embodiment 1 and (ii) a heavy hole level and a light hole level.

FIG. 17 is a second graph showing calculation results of a relation between (i) an Al composition ratio of the well layer according to Embodiment 1 and (ii) a heavy hole level and a light hole level.

FIG. 18 is a third graph showing calculation results of a relation between (i) an Al composition ratio of the well layer according to Embodiment 1 and (ii) a heavy hole level and a light hole level.

FIG. 19 is a schematic diagram illustrating an outline of an energy band structure of a semiconductor light-emitting element according to Variation 1 of Embodiment 1.

FIG. 20 is a schematic diagram illustrating energy difference ΔEc2 between conduction band potential energies of a p-side barrier layer and a p-side guide layer according to Variation 1 of Embodiment 1, and energy difference ΔEv2 between valence band potential energies of the p-side barrier layer and the p-side guide layer.

FIG. 21 is a graph showing relations between an Al composition ratio of the p-side barrier layer according to Variation 1 of Embodiment 1 and energy differences ΔEc2 and ΔEv2.

FIG. 22 is a schematic diagram illustrating an outline of an energy band structure of a semiconductor light-emitting element according to Variation 2 of Embodiment 1.

FIG. 23 is a schematic diagram illustrating an outline of an energy band structure of a semiconductor light-emitting element according to Variation 3 of Embodiment 1.

FIG. 24 is a schematic diagram illustrating an outline of an energy band structure of a semiconductor light-emitting element according to Variation 4 of Embodiment 1.

FIG. 25 is a schematic diagram illustrating an outline of an energy band structure of a semiconductor light-emitting element according to Variation 5 of Embodiment 1.

FIG. 26 is a schematic diagram illustrating an outline of an energy band structure of a semiconductor light-emitting element according to Variation 6 of Embodiment 1.

FIG. 27 is a cross-sectional view illustrating a configuration of a light-emitting end face portion of a semiconductor light-emitting element according to Variation 7 of Embodiment 1.

FIG. 28 is a cross-sectional view schematically illustrating an entire configuration of a semiconductor light-emitting element according to Embodiment 2.

FIG. 29 is a cross-sectional view schematically illustrating an entire configuration of a semiconductor light-emitting element according to Embodiment 3.

FIG. 30 is a cross-sectional view schematically illustrating a size of each part of the semiconductor light-emitting element according to Embodiment 3.

FIG. 31 is a cross-sectional view schematically illustrating a mounted state of the semiconductor light-emitting element according to Embodiment 3.

FIG. 32 is a graph showing a distribution of shear stress σxy relative to a position of an active layer of the semiconductor light-emitting element according to Embodiment 3 in the x-axis direction.

FIG. 33 is a flow chart illustrating steps of a semiconductor light-emitting element manufacturing method according to Embodiment 4.

### DESCRIPTION OF EMBODIMENTS

Hereinafter, embodiments of the present disclosure will be described with reference to the drawings. The embodiments described below each show a specific example of the present disclosure. The numerical values, shapes, materials, constituent elements, the arrangement and connection of the constituent elements, etc. in the following embodiments are mere examples, and thus are not intended to limit the scope of the present disclosure.

Additionally, the figures are schematic diagrams and are not necessarily precise illustrations. Accordingly, the figures are not necessarily to scale etc. It should be noted that, in the figures, elements that are substantially the same have the same reference signs, and duplicate description is omitted or simplified.

Moreover, in this Specification, the terms “above” and “below” do not refer to the upward (vertically upward) direction and downward (vertically downward) direction in terms of absolute spatial recognition, and are used as terms defined by relative positional relations based on the stacking order of a stacked structure. Furthermore, the terms “above” and “below” are applied not only when two structural components are disposed with a gap therebetween and another structural component is interposed between the two structural components, but also when two structural components are disposed in contact with each other.

### Embodiment 1

A semiconductor light-emitting element according to Embodiment 1 will be described.

### 1-1. Entire Configuration

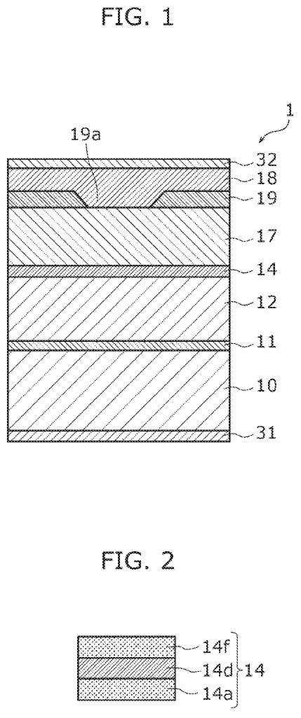

First, an entire configuration of the semiconductor light-emitting element according to the present embodiment will be described. FIG. 1 is a cross-sectional view schematically illustrating an entire configuration of semiconductor light-emitting element 1 according to the present embodiment. FIG. 2 is a cross-sectional view schematically illustrating a detailed configuration of active layer 14 included in semiconductor light-emitting element 1 according to the present embodiment.

Semiconductor light-emitting element 1 emits light in response to application of a voltage thereto. In the present embodiment, semiconductor light-emitting element 1 emits laser light having a wavelength of at least approximately 900 nm and at most approximately 980 nm. More specifically, semiconductor light-emitting element 1 emits laser light having a wavelength of approximately 915 nm. FIG. 1 shows a cross-section of semiconductor light-emitting element 1 perpendicular to a resonance direction of laser light. Although a resonator length of semiconductor light-emitting element 1, that is, a distance between end face portions in the resonance direction of the laser light is not particularly limited, the resonator length of semiconductor light-emitting element 1 is at least 2 mm in the present embodiment. Moreover, the resonator length of semiconductor light-emitting element 1 may be at least 4 mm. Since such an increased resonator length makes it possible to reduce thermal resistance of semiconductor light-emitting element 1, it is possible to improve heat dissipation of semiconductor light-emitting element 1. As a result, it is possible to increase optical output thermally saturated by semiconductor light-emitting element 1. As shown in FIG. 1, semiconductor light-emitting element 1 includes substrate 10, buffer layer 11, n-type clad layer 12, active layer 14, p-type clad layer 17, current confinement layer 19, contact layer 18, n-side electrode 31, and p-side electrode 32.

Substrate 10 is a plate-like component that is a base of semiconductor light-emitting element 1. In the present embodiment, substrate 10 is an n-type GaAs substrate.

Buffer layer 11 is for reducing a strain due to a lattice misfit between substrate 120 and n-type clad layer 12. Although a configuration of buffer layer 11 is not particularly limited, buffer layer 11 is an n-type GaAs layer having a thickness of 0.5 μm in the present embodiment. Buffer layer 11 is doped with, as impurities, Si having a concentration of 3×10¹⁷ cm⁻³.

n-type clad layer 12 is disposed above substrate 10. n-type clad layer 12 has a lower refractive index and a larger band gap energy than active layer 14 does. Although a configuration of n-type clad layer 12 is not particularly limited, n-type clad layer 12 is an n-type Al_{0.305}Ga_{0.695}As layer having a thickness of 4 μm in the present embodiment. n-type clad layer 12 is doped with, as impurities, Si having a concentration of 1×10¹⁸ cm⁻³.

Active layer 14 is an emission layer disposed above n-type clad layer 12 and having a quantum well structure. In the present embodiment, as shown in FIG. 2, active layer 14 includes n-side first barrier layer 14a, well layer 14d, and p-side barrier layer 14f.

Well layer 14d is a quantum well layer disposed between n-side first barrier layer 14a and p-side barrier layer 14f. In the present embodiment, well layer 14d is an Al_{0.27}Ga_{0.67}In_{0.25}As layer having a thickness of 6 nm.

n-side first barrier layer 14a is a blocking layer disposed on an n-type clad layer 12 side of well layer 14d. In the present embodiment, n-side first barrier layer 14a is an Al_{0.27}Ga_{0.73}As layer having a thickness of 7 nm.

p-side first barrier layer 14f is a blocking layer disposed on a p-type clad layer 17 side of well layer 14d. In the present embodiment, p-side barrier layer 14f is an Al_{0.45}In_{0.10}Ga_{0.45}As layer having a thickness of 7 nm. The thickness of p-side barrier layer 14f is determined so that a wave function of electrons in well layer 14d is attenuated to less than 1% of the maximum amplitude at an end face portion of p-side barrier layer 14f on the p-type clad layer 17 side. For this reason, it is possible to suppress the transmission of the electrons in well layer 14d through p-side barrier layer 14f due to a tunnel effect, that is, the occurrence of leakage current. Moreover, p-side barrier layer 14f has a compression strain, and when the thickness of p-side barrier layer 14f exceeds a critical thickness, a lattice defect occurs. Accordingly, the thickness of p-side barrier layer 14f may be at least 3 nm and be less than or equal to the critical thickness so that it is possible to suppress the transmission of the electrons in well layer 14d due to the tunnel effect. Here, a critical thickness can be defined as 20/Q, where an absolute value of the lattice misfit of p-side barrier layer 14f relative to substrate 10 is Q %.

p-type clad layer 17 is disposed above active layer 14. p-type clad layer 17 has a lower refractive index and a larger band gap energy than active layer 14 does. Although a configuration of p-type clad layer 17 is not particularly limited, p-type clad layer 17 is an Al_{0.7}Ga_{0.3}As layer having a thickness of 0.7 μm. p-type clad layer 17 is doped with, as impurities, C (carbon atoms) having a concentration of 2×10¹⁸ cm⁻³.

Contact layer 18 is disposed above p-type clad layer 17 and is in contact with p-side electrode 32. Although a configuration of contact layer 18 is not particularly limited, contact layer 18 is a p-type GaAs layer having a thickness of 0.4 μm in the present embodiment. Contact layer 18 is doped with, as impurities, C having a concentration of 2×10¹⁸ cm⁻³.

Current confinement layer 19 is disposed above p-type clad layer 17 and functions to cause a current to concentratively flow through a narrow region in semiconductor light-emitting element 1, that is, confine a current to a portion of a region. In the present embodiment, current confinement layer 19 is an n-type semiconductor layer disposed between p-type clad layer 17 and contact layer 18. Current confinement layer 19 includes opening 19a elongated along the laser resonance direction of semiconductor light-emitting element 1. Contact layer 18 is disposed in opening 19a. As a result, a current flows through only opening 19a of current confinement layer 19. In other words, the current is confined to opening 19a. Accordingly, since the current flows through a region of active layer 14 below opening 19a, this region serves as a light-emitting portion. Although a configuration of current confinement layer 19 is not particularly limited, current confinement layer 19 is an n-type GaAs layer having a thickness of 0.25 μm in the present embodiment. Current confinement layer 19 is doped with, as impurities, Si having a concentration of 2×10¹⁸ cm⁻³.

n-side electrode 31 is disposed on a lower principal surface (i.e., among principal surfaces of substrate 10, a principal surface on the back side of a principal surface on which the semiconductor layer is disposed) of substrate 10. Although a configuration of n-side electrode 31 is not particularly limited, n-side electrode 31 includes the following films stacked in order from a substrate 10 side in the present embodiment: an AuGe film having a thickness of 90 nm; an Ni film having a thickness of 20 nm; an Au film having a thickness of 50 nm; a Ti film having a thickness of 100 nm; a Pt film having a thickness of 50 nm; a Ti film having a thickness of 50 nm; a Pt film having a thickness of 100 nm; and an Au film having a thickness of 500 nm.

p-side electrode 32 is disposed above contact layer 18. p-side electrode 32 is in ohmic contact with contact layer 18. Although a configuration of p-side electrode 32 is not particularly limited, p-side electrode 32 includes the following films stacked in order from a contact layer 18 side in the present embodiment: a Ti film having a thickness of 50 nm; a Pt film having a thickness of 150 nm; and an Au film having a thickness of 50 nm.

### 1-2. Functions and Effects

Next, functions and effects of semiconductor light-emitting element 1 according to the present embodiment will be described.

### 1-2-1. Functions and Effects of Active Layer

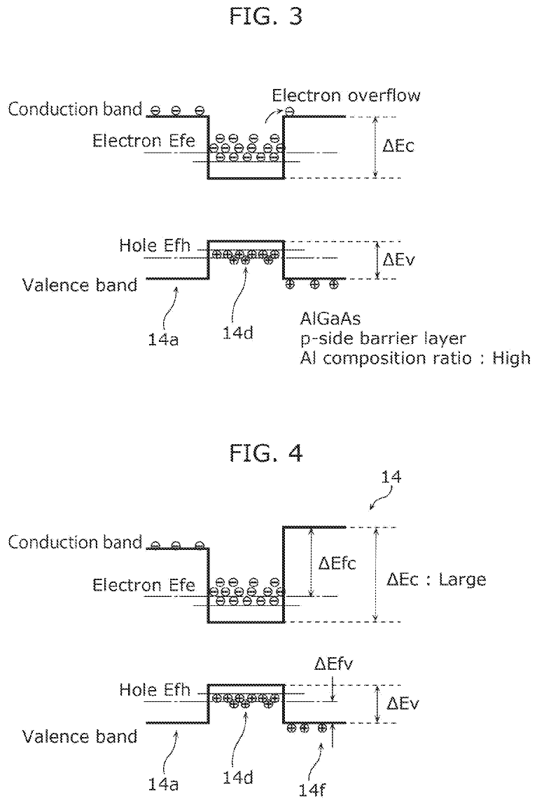

First, an outline of functions and effects of active layer 14 of semiconductor light-emitting element 1 according to the present embodiment will be described with reference to FIG. 3 and FIG. 4, by comparison with functions of a semiconductor light-emitting element of a comparative example. FIG. 3 and FIG. 4 are schematic diagrams illustrating outlines of energy band structures of active layers according to the comparative example and the present embodiment, respectively. It should be noted that FIG. 3 and FIG. 4 each also show energy difference ΔEc between conduction band potential energies of a p-side barrier layer and a well layer, energy difference ΔEv between valance band potential energies of the p-side barrier layer and the well layer, Fermi level Efe of electrons, and Fermi level Efh of holes. Additionally, FIG. 4 shows energy difference ΔEfc between Fermi level Efe of the electrons and a conduction band potential energy of p-side barrier layer 14f, and energy difference ΔEfv between Fermi level Efh of the holes and a valance band potential energy of p-side barrier layer 14f.

As with active layer 14 according to the present embodiment, the active layer of the comparative example shown in FIG. 3 includes n-side first barrier layer 14a, well layer 14d, and a p-side barrier layer. The p-side barrier layer of the comparative example differs from p-side barrier layer 14f according to the present embodiment in composition. The p-side barrier layer of the comparative example is an AlGaAs layer and does not contain In.

The following examines a case in which energy difference ΔEc is increased to control electron overflow in the active layer of the comparative example including such a p-side barrier layer. In this case, it is possible to increase energy difference ΔEc by increasing the Al composition ratio of the p-side barrier layer. Concomitantly, however, this also increases energy difference ΔEv. Accordingly, since energy required for holes to cross the p-side barrier layer also increases, an operating voltage of the semiconductor light-emitting element increases.

On the other hand, in active layer 14 according to the present embodiment shown in FIG. 4, p-side barrier layer 14f contains In, and n-side first barrier layer 14a has a lower In composition ratio than p-side barrier layer 14f does. Moreover, n-side first barrier layer 14a has a lower band gap energy than p-side barrier layer 14f does. As shown in FIG. 4, such active layer 14 makes it possible to increase energy differences ΔEc and ΔEfc while suppressing an increase in energy differences ΔEv and ΔEfv. Accordingly, it is possible to control electron overflow by increasing energy differences ΔEc and ΔEfc while suppressing an increase in operating voltage of semiconductor light-emitting element 1 by suppressing an increase in energy differences ΔEv and ΔEfv.

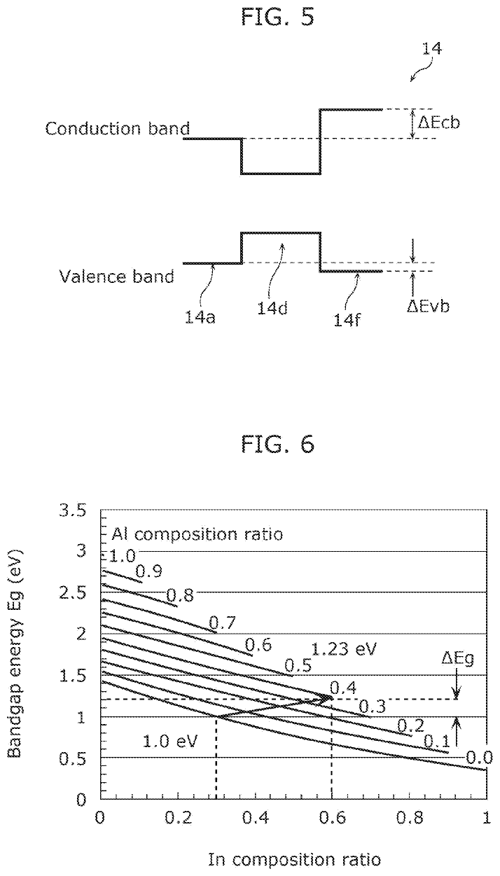

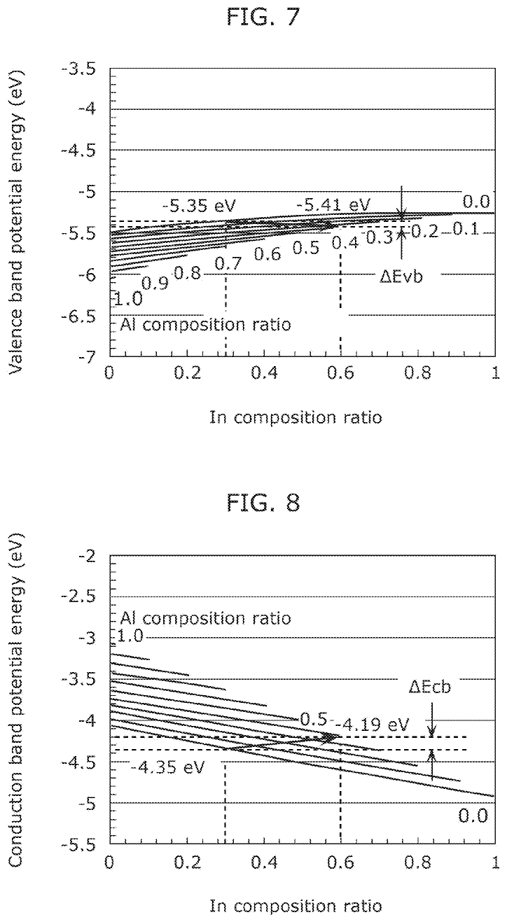

The above-described characteristics of active layer 14 according to the present embodiment will be described in detail with reference to FIG. 5 to FIG. 8. FIG. 5 is a schematic diagram illustrating an energy difference between conduction band potential energies of n-side first barrier layer 14a and p-side barrier layer 14f of active layer 14 according to the present embodiment, and an energy difference between valance band potential energies of n-side first barrier layer 14a and p-side barrier layer 14f of active layer 14. As shown in FIG. 5, the energy difference between the conduction band potential energies of n-side first barrier layer 14a and p-side barrier layer 14f is defined as ΔEcb, and the energy difference between the valance band potential energies of n-side first barrier layer 14a and p-side barrier layer 14f is defined as ΔEvb. FIG. 6, FIG. 7, and FIG. 8 are each a graph illustrating In and Al composition ratio dependence of band gap energy (Eg), valance band potential energy, and conduction band potential energy of an AlGaInAs-based material. In FIG. 6, FIG. 7, and FIG. 8, the vertical axis represents band gap energy, valance band potential energy, and conduction band potential energy, and the horizontal axis represents an In composition ratio. In addition, FIG. 6 to FIG. 8 each show a graph when an Al composition ratio is changed as a parameter from 0 to 1 by an increment of 0.1.

As shown in FIG. 6, the band gap energy decreases with an increase in In composition ratio, and increases with an increase in Al composition ratio. For example, a difference (ΔEg shown in FIG. 6) between a band gap energy of approximately 1.0 eV of Ga_{0.7}In_{0.3}As and a band gap energy of approximately 1.23 eV of Al_{0.4}In_{0.6}As, that is, the sum of energy differences ΔEcb and ΔEvb is approximately 0.23 eV. As stated above, even when the In composition ratio increases in the AlGaInAs-based material, it is possible to increase the band gap energy by increasing the Al composition ratio.

As shown in FIG. 7 and FIG. 8, the valance band potential energy increases with an increase in In composition ratio, and the conduction band potential energy decreases with an increase in In composition ratio. On the other hand, the valance band potential energy decreases with an increase in Al composition ratio, and the conduction band potential energy increases with an increase in Al composition ratio. Moreover, the conduction band potential energy has a greater amount of change relative to changes in Al composition ratio and In composition ratio than the valance band potential energy does. For example, energy difference ΔEvb between a valance band potential energy of approximately −5.35 eV of Ga_{0.7}In_{0.3}As and a valance band potential energy of approximately −5.41 eV of Al_{0.4}In_{0.6}As is approximately 0.06 eV, whereas energy difference ΔEcb is approximately 0.16 eV. In this case, energy difference ΔEcb is 2.7 times energy difference ΔEvb. As stated above, it is possible to change the conduction band potential energy more greatly than the valance band potential energy by adjusting the Al composition ratio and the In composition ratio in the AlGaInAs-based material. Accordingly, it is possible to increase energy differences ΔEc and ΔEfc while suppressing an increase in energy differences ΔEv and ΔEfv as shown in FIG. 4, by adjusting each composition in n-side first barrier layer 14a and p-side barrier layer 14f using the AlGaInAs-based material. In the present embodiment, n-side first barrier layer 14a has a lower In composition ratio than p-side barrier layer 14f does, and n-side first barrier layer 14a has a smaller band gap energy than p-side barrier layer 14f does. For this reason, it is possible to increase energy differences ΔEc and ΔEfc while suppressing an increase in energy differences ΔEv and ΔEfv. As a result, it is possible to control the electron overflow from the well layer while suppressing an increase in voltage necessary for electrical conduction of holes, that is, an increase in operating voltage of semiconductor light-emitting element 1.

When an Al composition ratio and an In composition ratio of n-side first barrier layer 14a are denoted by ybn1 and xbn1, respectively, a composition of n-side first barrier layer 14a is represented by Al_{ybn1}Ga_{1-xbn1-ybn1}In_{xbn1}As. When an Al composition ratio and an In composition ratio of p-side barrier layer 14f are denoted by ybp1 and xbp1, respectively, a composition of p-side barrier layer 14f is represented by Al_{ybp1}Ga_{1-xbp1-ybp1}In_{xbp1}As. In the present embodiment, with regard to those composition ratios, 0≤ybn1≤1,0≤xbn1<1,0<ybp1<1,0<xbp1<1, and xbn1<xbp1 are satisfied. It is possible to cause the In composition ratio of n-side first barrier layer 14a to be lower than the In composition ratio of p-side barrier layer 14f, and the band gap of n-side first barrier layer 14a to be smaller than the band gap of p-side barrier layer 14f, using n-side first barrier layer 14a and p-side barrier layer 14f having such compositions.

In the present embodiment, with regard to the Al composition ratios, ybn1<ybp1 is satisfied. Accordingly, since energy difference ΔEc between the conduction band potential energies of p-side barrier layer 14f and n-side first barrier layer 14a increases, it is possible to further control the electron overflow from well layer 14d.

In the present embodiment, when an Al composition ratio and an In composition ratio of well layer 14d are denoted by xw and yw, respectively, a composition of well layer 14d is represented by Al_{yw}Ga_{1-xw-yw}In_{xw}As, and 0≤yw<1 and 0<xw<1 are satisfied. When the composition of well layer 14d is Al_{yw}Ga_{1-xw-yw}In_{xw}As, it is possible to adjust the magnitude of a strain in well layer 14d and a conduction band potential energy difference and a valance band potential energy difference between well layer 14d and each barrier layer, by adjusting the Al composition ratio, Ga composition ratio, and In composition ratio of well layer 14d. Accordingly, it is possible to adjust an oscillation wavelength of semiconductor light-emitting element 1 and control the electron overflow from well layer 14d.

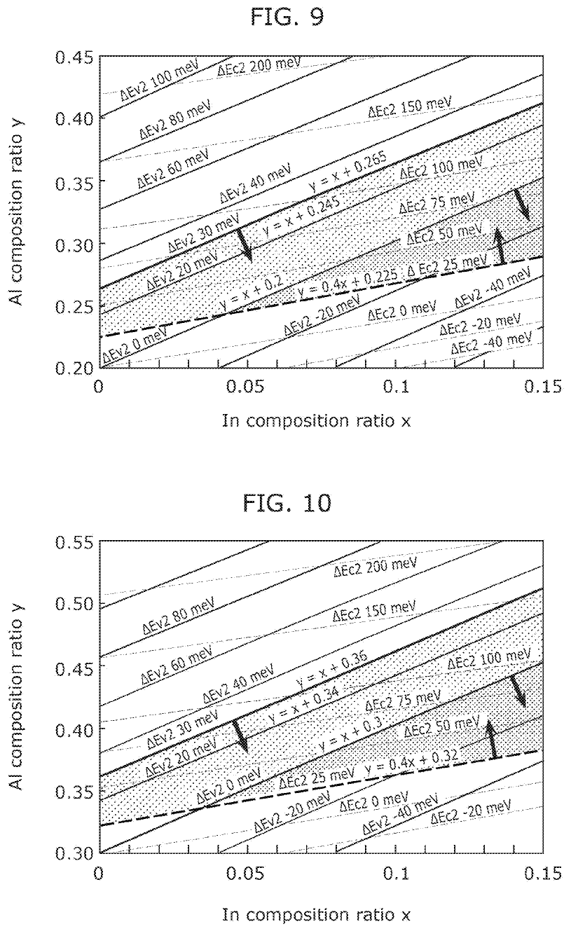

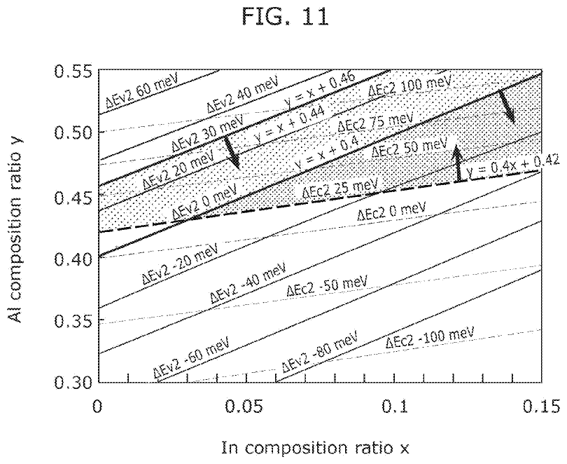

Next, relations between Al composition ratios and In composition ratios of n-side first barrier layer 14a and p-side barrier layer 14f according to the present embodiment will be described in further details with reference to FIG. 9 to FIG. 11. FIG. 9, FIG. 10, and FIG. 11 are each a graph showing relations between (i) energy difference ΔEc2 between conduction band potential energies of an AlGaInAs-based material and each of Al_{0.2}Ga_{0.7}As, Al_{0.3}Ga_{0.7}As, and Al_{0.4}Ga_{0.6}As, (ii) energy difference ΔEv2 between valance band potential energies of the AlGaInAs-based material and each of Al_{0.2}Ga_{0.8}As, Al_{0.3}Ga_{0.7}As, and Al_{0.4}Ga_{0.6}As, and (iii) a composition of the AlGaInAs-based material. The horizontal axis and vertical axis of each of FIG. 9 to FIG. 11 represent In composition ratio x and Al composition ratio y of the AlGaInAs-based material, respectively. FIG. 9 to FIG. 11 each show relations between In composition ratio x and Al composition ratio y at which energy differences ΔEc2 and energy differences ΔEv2 have predetermined values, using broken lines and solid lines. For example, FIG. 9 shows the relations between In composition ratio x and Al composition ratio y at which energy differences ΔEc2 are −50 meV, −20 meV, 0 meV, 25 meV, 50 meV, 75 meV, 100 meV, 150 meV, and 200 meV, using the respective broken lines. In addition, FIG. 9 shows the relations between In composition ratio x and Al composition ratio y at which energy differences ΔEv2 are −40 meV, −20 meV, 0 meV, 30 meV, 40 meV, 60 meV, 80 meV, and 100 meV, using the respective solid lines.

For example, in order to cause an energy difference between conduction band potential energies of n-side first barrier layer 14a including Al_{0.2}Ga_{0.8}As and p-side barrier layer 14f including Al_{y}Ga_{1-x-y}InₓAs to be at least 25 meV so that electron overflow from well layer 14d is controlled, In composition ratio x and Al composition ratio y corresponding to points on line y=0.4x+0.225 and in regions above the line may be used, the line causing ΔEc2 shown in FIG. 9 to be 25 meV. In other words, with regard to In composition ratio x and Al composition ratio y, y≥0.4x+0.225 may be satisfied.

Moreover, in order to cause an energy difference between valance band potential energies of n-side first barrier layer 14a including Al_{0.2}Ga_{0.8}As and p-side barrier layer 14f including Al_{y}Ga_{1-x-y}InₓAs to be at least 30 meV so that an increase in operating voltage of semiconductor light-emitting element 1 is suppressed, In composition ratio x and Al composition ratio y corresponding to points on line y=x+0.265 and in regions below the line may be used, the line causing ΔEv2 shown in FIG. 9 to be 30 meV. In other words, with regard to In composition ratio x and Al composition ratio y, y≤x+0.265 may be satisfied.

In order to cause the energy difference between the valance band potential energies of n-side first barrier layer 14a including Al_{0.2}Ga_{0.8}As and p-side barrier layer 14f including Al_{y}Ga_{1-x-y}InₓAs to be at most 0 meV so that the increase in operating voltage of semiconductor light-emitting element 1 is further suppressed, as shown in FIG. 9, with regard to In composition ratio x and Al composition ratio y, y≤x+0.2 may be satisfied. In addition, in order to cause the energy difference between the conduction band potential energies of n-side first barrier layer 14a including Al_{0.2}Ga_{0.8}As and p-side barrier layer 14f including Al_{y}Ga_{1-x-y}InₓAs to be at least 50 meV so that the electron overflow from well layer 14d is further controlled, as shown in FIG. 9, with regard to In composition ratio x and Al composition ratio y, y≥0.4x+0.255 may be satisfied.

Accordingly, when n-side first barrier layer 14a including Al_{0.2}Ga_{0.8}As is used, in order to control the electron overflow from well layer 14d while suppressing the increase in operating voltage of semiconductor light-emitting element 1, with regard to In composition ratio x and In composition ratio y of p-side barrier layer 14f including Al_{y}Ga_{1-x-y}InₓAs, y≥0.4x+0.225 and y≤x+0.265 may be satisfied. Combinations of In composition ratio x and Al composition ratio y that satisfy these relations correspond to points in a hatched region shown in FIG. 9. In addition, y≤x+0.2 may be satisfied in order to further suppress the increase in operating voltage of semiconductor light-emitting element 1 (ΔEv2≤0 meV). Combinations of In composition ratio x and Al composition ratio y that satisfy this relation correspond to points in a more densely-dotted region of the hatched region shown in FIG. 9. Additionally, y≥0.4x+0.255 may be satisfied in order to further control the electron overflow from well layer 14d (ΔEc2≥50 meV).

As with the case in which n-side first barrier layer 14a including Al_{0.2}Ga_{0.8}As is used, when n-side first barrier layer 14a including Al_{0.3}Ga_{0.7}As is used, it is possible to determine a composition of p-side barrier layer 14f from the graph shown in FIG. 10. To put it another way, in order to control electron overflow from well layer 14d (ΔEc2≥25 meV) while suppressing an increase in operating voltage of semiconductor light-emitting element 1 (ΔEv2≤30 meV), as shown in FIG. 10, with regard to In composition ratio x and Al composition ratio y of p-side barrier layer 14f including Al_{y}Ga_{1-x-y}InₓAs, y≥0.4x+0.32 and y≤x+0.36 may be satisfied. Combinations of In composition ratio x and Al composition ratio y that satisfy these relations correspond to points in a hatched region shown in FIG. 10. In addition, y≤x+0.3 may be satisfied in order to further suppress the increase in operating voltage of semiconductor light-emitting element 1 (ΔEv2≤0 meV). Combinations of In composition ratio x and Al composition ratio y that satisfy this relation correspond to points in a more densely-dotted region of the hatched region shown in FIG. 10. Additionally, y≥0.4x+0.355 may be satisfied in order to further control the electron overflow from well layer 14d (ΔEc2≥50 meV).

As with the case in which n-side first barrier layer 14a including Al_{0.2}Ga_{0.8}As is used, when n-side first barrier layer 14a including Al_{0.4}Ga_{0.6}As is used, it is possible to determine a composition of p-side barrier layer 14f from the graph shown in FIG. 11. To put it another way, in order to control electron overflow from well layer 14d (ΔEc2≥25 meV) while suppressing an increase in operating voltage of semiconductor light-emitting element 1 (ΔEv2≤30 meV), as shown in FIG. 11, with regard to In composition ratio x and Al composition ratio y of p-side barrier layer 14f including Al_{y}Ga_{1-x-y}InₓAs, y≥0.4x+0.42 and y≤x+0.46 may be satisfied. Combinations of In composition ratio x and Al composition ratio y that satisfy these relations correspond to points in a hatched region shown in FIG. 11. In addition, y≤x+0.4 may be satisfied in order to further suppress the increase in operating voltage of semiconductor light-emitting element 1 (ΔEv2≤0 meV). Combinations of In composition ratio x and Al composition ratio y that satisfy this relation correspond to points in a more densely-dotted region of the hatched region shown in FIG. 11. Additionally, y≥0.4x+0.45 may be satisfied in order to further control the electron overflow from well layer 14d (ΔEc2≥50 meV).

The relations shown in FIG. 9 to FIG. 11 are summarized as follows. When the composition of n-side first barrier layer 14a and the composition of p-side barrier layer 14f are represented by Al_{ybn1}Ga_{1-xbn1-ybn1}In_{xbn1}As and Al_{ybp1}Ga_{1-xbp1-ybp1}In_{xbp1}As, respectively, 0.2≤ybn1≤0.4ybp1≤xbp1+0.975ybn1+0.069, ybp1≥0.4xbp1+0.975ybn1+0.029, and xpb1≤0.15 may be satisfied. This makes it possible to control the electron overflow from well layer 14d (ΔEc2≥25 meV) while suppressing the increase in operating voltage of semiconductor light-emitting element 1 (ΔEv2≤30 meV). Moreover, causing Al composition ratio ybn1 of n-side first barrier layer 14a to be at least 0.2 and at most 0.4, it is possible to highly accurately control a vertical light distribution and to reduce a loss in a waveguide while suppressing a significant decrease in light confinement factor.

Furthermore, ybp1≤xbp1+0.975ybn1+0.049 may be satisfied. This makes it possible to further suppress the increase in operating voltage of semiconductor light-emitting element 1 (ΔEv2<20 meV).

Moreover, ybp1≤xbp1+ybn1 may be satisfied. This makes it possible to further suppress the increase in operating voltage of semiconductor light-emitting element 1 (ΔEv2≤0 meV).

Furthermore, ybp1≥0.4xbp1+0.975ybn1+0.061 may be satisfied. This makes it possible to further control the electron overflow from well layer 14d (ΔEv2≤50 meV).

### 1-2-2. Functions and Effects of Clad Layer

Next, functions and effects of n-type clad layer 12 and p-type clad layer 17 according to the present embodiment will be described.

In the present embodiment, n-type clad layer 12 has a smaller band gap energy than p-type clad layer 17 does. As a result, n-type clad layer 12 has a higher refractive index than p-type clad layer 17 does. For this reason, a light distribution in a direction vertical to a principal surface of substrate 10 is skewed toward an n-type clad layer 12 side. Here, in an n-type semiconductor layer, it is possible to reduce a resistance value by causing a doping concentration of n-type impurities to be in a range from 1×10¹⁶ cm⁻³ to 1×10¹⁸ cm⁻³. On the other hand, in a p-type semiconductor layer, it is not possible to reduce a resistance value if a doping concentration of p-type impurities is not caused to be at least 1×10¹⁸ cm⁻³. Consequently, a free carrier loss of light in the waveguide of semiconductor light-emitting element 1 is greater in the p-type semiconductor layer having a higher doping concentration than the n-type semiconductor layer does. Accordingly, it is possible to reduce a waveguide loss by skewing a light distribution toward the n-type clad layer 12 side as in semiconductor light-emitting element 1 according to the present embodiment.

The skew of the light distribution toward the n-type clad layer 12 side causes a decrease in light confinement factor in the vertical direction (in the direction vertical to the principal surface of substrate 10) relative to well layer 14d that is an emission layer. For this reason, when semiconductor light-emitting element 1 performs laser oscillation, the number of operating carriers easily increases in well layer 14d, and electrons having a smaller effective mass than holes easily overflow from well layer 14d to p-side barrier layer 14f. In semiconductor light-emitting element 1 according to the present embodiment, however, since energy difference ΔEc between conduction band potential energies of p-side barrier layer 14f and n-side first barrier layer 14a is large, it is possible to control the electron overflow. Accordingly, it is possible to achieve a semiconductor light-emitting element that is capable of improving temperature characteristics more greatly than the conventional semiconductor light-emitting elements while suppressing the increase in operating voltage, has a high slope efficiency, and operates with a low operating current.

Moreover, when an Al composition ratio of n-type clad layer 12 is denoted by yn1, a composition of n-type clad layer 12 is represented by Al_{yn1}Ga_{1-yn1}As; when an Al composition ratio of p-type clad layer 17 is denoted by yp1, a composition of p-type clad layer 17 is represented by Al_{yp1}Ga_{1-yp1}As; and 0<yn1<yp1<1 is satisfied.

Since Al composition ratio yn1 of n-type clad layer 12 is lower than Al composition ratio yp1 of p-type clad layer 17 as above, n-type clad layer 12 has a higher refractive index than p-type clad layer 17 does. Concomitantly, the vertical light distribution is skewed toward the n-type clad layer 12 side. As stated above, since the free carrier loss of the light in the waveguide of semiconductor light-emitting element 1 is greater in the p-type semiconductor layer having a higher doping concentration than the n-type semiconductor layer does, it is possible to reduce the waveguide loss by skewing the vertical light distribution toward the n-type semiconductor layer.

Since the skew of the light distribution toward the n-type clad layer 12 side causes a decrease in light confinement factor in the vertical direction relative to well layer 14d that is an emission layer, as stated above, the electrons easily overflow from well layer 14d to p-side barrier layer 14f. In semiconductor light-emitting element 1 according to the present embodiment, however, since energy difference ΔEc between the conduction band potential energies of p-side barrier layer 14f and n-side first barrier layer 14a is large, it is possible to control the electron overflow. Accordingly, it is possible to achieve semiconductor light-emitting element 1 that is capable of improving the temperature characteristics more greatly than the conventional semiconductor light-emitting elements while suppressing the increase in operating voltage, has a high slope efficiency, and operates with a low operating current.

### 1-2-3. Current-Voltage Characteristics

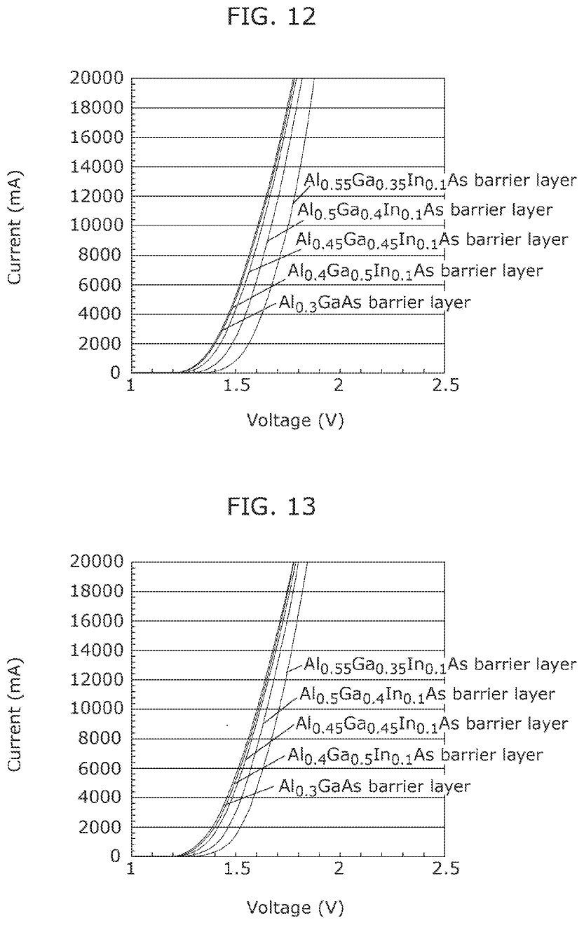

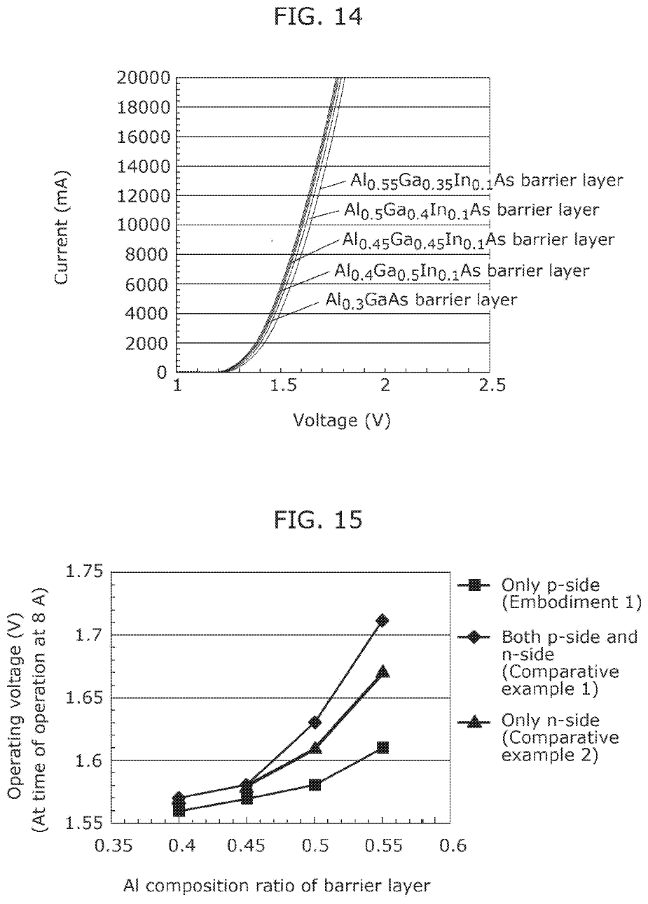

Next, current-voltage characteristics of semiconductor light-emitting element 1 according to the present embodiment will be described with reference to FIG. 12 to FIG. 15, as compared to comparative examples. FIG. 12, FIG. 13, and FIG. 14 are each a graph showing simulation results of current-voltage characteristics of a semiconductor light-emitting element according to each of Comparative Example 1, Comparative Example 2, and the present embodiment. In each of the graphs of FIG. 12 to FIG. 14, the horizontal axis and the vertical axis represent a voltage and a current applied to the semiconductor light-emitting element, respectively. FIG. 15 is a graph showing a relation between an Al composition ratio and an operating voltage of a quaternary barrier layer of each of the semiconductor light-emitting elements according to Comparative Example 1, Comparative Example 2, and the present embodiment. In FIG. 15, the horizontal axis and vertical axis of the graph represent an Al composition ratio and an operating voltage of the quaternary barrier layer, respectively. It should be noted that the operating voltage shown in FIG. 15 is an operating voltage when an operating current (i.e., a current applied to the semiconductor light-emitting element) is 8 A.

The semiconductor light-emitting element according to Comparative Example 1 differs from semiconductor light-emitting element 1 according to the present embodiment in that an n-side first barrier layer and a p-side barrier layer are identical quaternary barrier layers, that is, barrier layers including an AlGaInAs-based material. Al_{0.4} Ga_{0.5}In_{0.1}As, Al_{0.45}Ga_{0.45}In_{0.1}As, Al_{0.5}Ga_{0.4}In_{0.1}As, and Al_{0.55}Ga_{0.35}In_{0.1}As are used as compositions of the quaternary barrier layers. FIG. 12 also shows simulation results when a ternary barrier layer having a composition of Al_{0.3}Ga_{0.7}As is used. In addition, a well layer has a composition of Al_{0.04}Ga_{0.77}In_{0.19}As.

The semiconductor light-emitting element according to Comparative Example 2 differs from semiconductor light-emitting element 1 according to the present embodiment in that only an n-side first barrier layer is the same quaternary barrier layer as in Comparative Example 1, and a p-side barrier layer is a ternary barrier layer. The p-side barrier layer has a composition of Al_{0.3}Ga_{0.7}As. FIG. 13 also shows simulation results when a ternary barrier layer having a composition of Al_{0.3}Ga_{0.7}As is used as the n-side first barrier layer. In addition, a well layer has the same composition of Al_{0.04}Ga_{0.77}In_{0.19}As as in Comparative Example 1.

In semiconductor light-emitting element 1 according to the present embodiment, only p-side barrier layer 14f is the same quaternary barrier layer as in Comparative Example 1, and n-side first barrier layer 14a is a ternary barrier layer having a composition of Al_{0.3}Ga_{0.7}As. FIG. 14 also shows simulation results when the ternary barrier layer having the composition of Al_{0.3}Ga_{0.7}As is used as p-side barrier layer 14f. In addition, well layer 14d has the same composition of Al_{0.04}Ga_{0.77}In_{0.19}As as in Comparative Example 1 and Comparative Example 2.

As shown in FIG. 12 to FIG. 15, semiconductor light-emitting element 1 according to the present embodiment is capable of decreasing an operating voltage, as compared to the semiconductor light-emitting elements according to Comparative Example 1 and Comparative Example 2. Especially, semiconductor light-emitting element 1 produces a more remarkable effect of decreasing an operating voltage with an increase in Al composition ratio of the quaternary barrier layer. Since semiconductor light-emitting element 1 according to the present embodiment is capable of suppressing an increase in operating voltage even if the Al composition ratio of p-side barrier layer 14f is varied, semiconductor light-emitting element 1 is capable of increasing a degree of freedom in composition control for p-side barrier layer 14f. Accordingly, it is possible to improve yields in manufacturing semiconductor light-emitting element 1.

Additionally, since only p-side barrier layer 14f is the quaternary barrier layer in semiconductor light-emitting element 1 according to the present embodiment, semiconductor light-emitting element 1 is capable of suppressing an increase in operating voltage due to the composition variation in each barrier layer, as compared to a case in which both n-side first barrier layer 14a and p-side barrier layer 14f are the quaternary barrier layers.

### 1-2-4. Effect of Increase in Polarization Ratio

Next, an effect of an increase in polarization ratio (an intensity ratio of TE mode light to TM mode light) according to the present embodiment will be described.

In a semiconductor light-emitting element, a polarization ratio is reduced by TM mode light being generated when light holes and electrons are recombined. Moreover, since an active layer temperature and an operating carrier density increase when a conventional semiconductor light-emitting element is in a high-output operation, the number of light holes increases, and the TM mode light increases in intensity. As a result, a polarization ratio is reduced.

Furthermore, when a resonator length of a semiconductor light-emitting element is extended, a contact area of a submount etc. on which the semiconductor light-emitting element is mounted increases. This increases the influence of a strain on an active layer, the strain resulting from a warp of the semiconductor light-emitting element, irregularities of solder for mounting, etc. Concomitantly, an energy band structure of the active layer may change, and the number of light holes may increase.

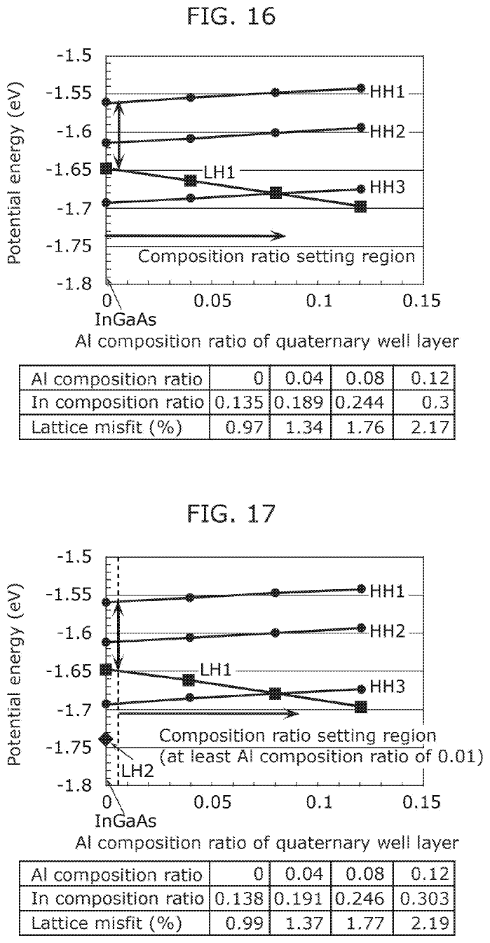

In view of above, in the present embodiment, an energy difference between a ground level for light holes and a ground level for heavy holes increases with an increase in a compression strain of well layer 14d. For this reason, the number of holes included in the light holes is decreased, and a probability of recombination between the light holes and the electrons is reduced. Hereinafter, relations between a heavy hole level and a light hole level of well layer 14d and a composition of well layer 14d according to the present embodiment will be described with reference to FIG. 16 to FIG. 18.

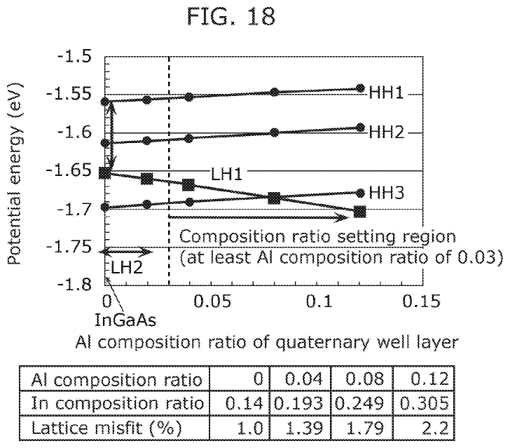

FIG. 16 to FIG. 18 are each a graph showing calculation results of relations between (i) an Al composition ratio of well layer 14d according to the present embodiment and (ii) a heavy hole (HH) level and a light hole (LH) level. It should be noted that a table that shows combinations of an Al composition ratio and an In composition ratio used in calculation and a lattice misfit corresponding to each of the combinations is provided below the graph shown in each of the figures. FIG. 16 to FIG. 18 each show the relations when different n-side first barrier layers 14a and different p-side barrier layers 14f are used. FIG. 16 shows the relations when Al_{0.24}Ga_{0.76}As and Al_{0.35}Ga_{0.55}In_{0.1}As are used as n-side first barrier layer 14a and p-side barrier layer 14f, respectively. FIG. 17 shows the relations when Al_{0.27}Ga_{0.73}As and Al_{0.37}Ga_{0.53}In_{0.1}As are used as n-side first barrier layer 14a and p-side barrier layer 14f, respectively. FIG. 18 shows the relations when Al_{0.3}Ga_{0.7}As and Al_{0.4}Ga_{0.5}In_{0.1}As are used as n-side first barrier layer 14a and p-side barrier layer 14f, respectively. In addition, an AlGaInAs-based quaternary semiconductor material film is used as well layer 14d.

Since substrate 10 of semiconductor light-emitting element 1 is the GaAs substrate in the present embodiment, it is possible to cause a compression strain in well layer 14d when the AlGaInAs-based quaternary semiconductor material is used for each of the barrier layers and well layer 14d. When well layer 14d has a compression strain, it is possible to decrease the number of light holes formed in a valance band of well layer 14d, by adjusting a composition of well layer 14d. Consequently, since it is possible to reduce a probability of recombination between light holes and electrons, it is possible to increase a polarization ratio of light outputted from semiconductor light-emitting element 1.

As shown in the respective tables of FIG. 16 to FIG. 18, increasing the Al composition ratio of well layer 14d makes it possible to increase the lattice misfit of well layer 14d, that is, increase the compression strain of well layer 14d. As shown in the respective graphs of FIG. 16 to FIG. 18, it is possible to increase the energy difference between the ground level for the heavy holes (HH1) and the ground level for the light holes (LH1). For example, when the composition of well layer 14d is represented by Al_{yw}Ga_{1-xw-yw}In_{xw}As as stated above, 0<yw<1 and 0<xw< may be satisfied. In this way, when well layer 14d has a compression strain because well layer 14d contains Al, it is possible to decrease the number of light holes formed in the valance band of well layer 14d. As a result, since it is possible to reduce the probability of recombination between the light holes and the electrons by decreasing the number of the light holes formed in the valance band of well layer 14d, it is possible to increase the polarization ratio (an intensity ratio of TE mode light to TM mode light) of the light outputted from semiconductor light-emitting element 1.

In the examples shown in FIG. 16 to FIG. 18, the Al composition ratio of well layer 14d may be set to an Al composition ratio that prevents high-order levels for light holes (e.g., LH2 shown in FIG. 17 and FIG. 18) other than the ground level for light holes (LH1) from appearing. For instance, the Al composition ratio may be at least 0 in the example shown in FIG. 16, the Al composition ratio may be at least approximately 0.005 in the example shown in FIG. 17, and the Al composition ratio may be at least approximately 0.03 in the example shown in FIG. 18. As shown in FIG. 16 to FIG. 18, with regard to light holes, a region for the Al composition ratio in which high-order levels for light holes other than the ground level (LH1) is not set is referred to as a composition ratio setting region.

It is possible to increase the polarization ratio of semiconductor light-emitting element 1 by determining the composition of well layer 14d in the above manner.

### 1-3. Variation 1

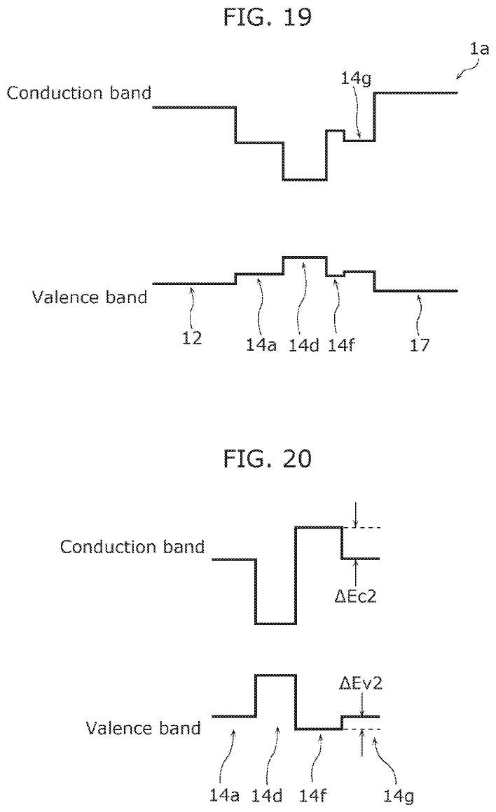

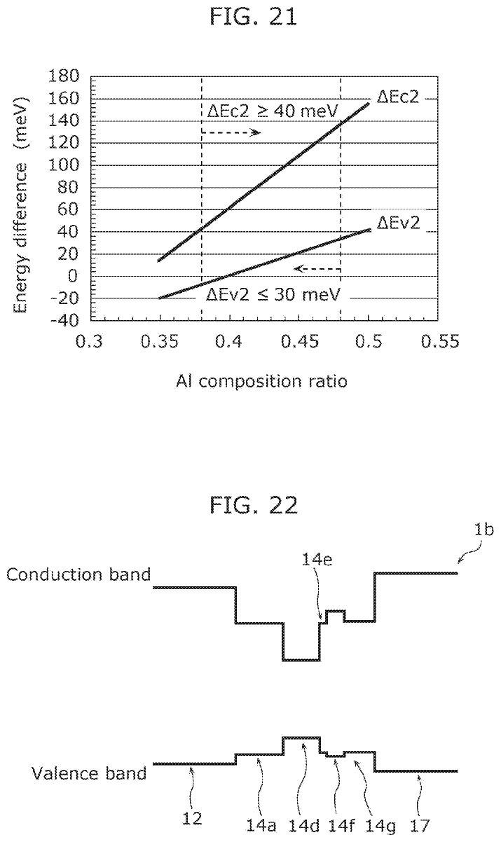

Next, a semiconductor light-emitting element according to Variation 1 of the present embodiment will be described with reference to FIG. 19 to FIG. 21. FIG. 19 is a schematic diagram illustrating an outline of an energy band structure of semiconductor light-emitting element 1a according to the present variation. FIG. 20 is a schematic diagram illustrating energy difference ΔEc2 between conduction band potential energies of p-side barrier layer 14f and p-side guide layer 14g according to the present variation, and energy difference ΔEv2 between valence band potential energies of p-side barrier layer 14f and p-side guide layer 14g. FIG. 21 is a graph showing relations between an Al composition ratio of p-side barrier layer 14f according to the present variation and energy differences ΔEc2 and ΔEv2.

As shown in FIG. 19, semiconductor light-emitting element 1a according to the present variation further includes p-side guide layer 14g that is disposed between p-side barrier layer 14f and p-type clad layer 17 and has a higher refractive index than p-type clad layer 17 does. In the present variation, p-side guide layer 14g is an Al_{0.27}Ga_{0.73}As film having a thickness of 30 nm. Since semiconductor light-emitting element 1a includes such p-side guide layer 14g, semiconductor light-emitting element 1a makes it possible to highly accurately control a vertical light distribution and suppress an excessive skew of the light distribution toward an n-type semiconductor layer side (i.e., the n-type clad layer 12 side). Accordingly, semiconductor light-emitting element 1a makes it possible to suppress a decrease in light confinement factor for confining light to well layer 14d in the vertical direction, and an increase in operating carrier density in well layer 14d. In other words, semiconductor light-emitting element 1a makes it possible to suppress a deterioration of temperature characteristics of semiconductor light-emitting element 1a. Moreover, since semiconductor light-emitting element 1a makes it possible to suppress an increase in free carrier loss due to impurity doping when p-side guide layer 14g is undoped, semiconductor light-emitting element 1a makes it possible to reduce a loss in a waveguide. As a result, it is possible to achieve a semiconductor laser element having excellent temperature characteristics and a high slope efficiency.

As shown in FIG. 20, when an energy difference between conduction band potential energies of p-side barrier layer 14f and p-side guide layer 14g is denoted by ΔEc2, and an energy difference between valance band potential energies of p-side barrier layer 14f and p-side guide layer 14g is denoted by ΔEv2, relations between the Al composition ratio of p-side barrier layer 14f and energy differences ΔEc2 and ΔEv2 are as shown by the graph shown in FIG. 21. Here, a composition of p-side guide layer 14g is Al_{0.3}Ga_{0.7}As, and an In composition ratio of p-side barrier layer 14f is set to 0.1.

In order to suppress a leak of electrons from well layer 14d to p-side guide layer 14g while sufficiently increasing a refractive index of p-side guide layer 14g, energy difference ΔEc2 between conduction band potential energies may be at least 40 meV. In this case, as shown in FIG. 21, the Al composition ratio of p-side barrier layer 14f may be at least approximately 0.38. Moreover, in order to suppress an increase in operating voltage of semiconductor light-emitting element 1a by reducing energy necessary to supply holes to well layer 14d, energy difference ΔEv2 may be at most 30 meV. In this case, as shown in FIG. 21, the Al composition ratio of p-side barrier layer 14f may be at least approximately 0.48.

As with the relations between the Al composition ratio and In composition ratio of p-side barrier layer 14f, it is possible to define relations between the Al composition ratio of p-side guide layer 14g and the Al composition ratio and In composition ratio of p-side barrier layer 14f. When an Al composition ratio of p-side guide layer 14g is denoted by ygp1, a composition of p-side guide layer 14g is represented by Al_{ygp1}Ga_{1-ygp1}As; and when an Al composition ratio and an In composition ratio of p-side barrier layer 14f are denoted by ybp1 and xbp1, respectively, ybp1≤xbp1+0.975ygp1+0.069, ybp1≥0.4×bp1+0.975ygp1+0.029, and 0.2≤ygp1≤0.4 may be satisfied.

p-side guide layer 14g having such a composition is substantially lattice-matched with substrate 10 including a GaAs substrate. For this reason, it is possible to cause the thickness of p-side barrier layer 14f having a compressive lattice misfit to be less than or equal to a critical thickness. Accordingly, it is possible to suppress a decrease in crystallinity of p-side barrier layer 14f.

When well layer 14d is a quaternary semiconductor material film containing Al, the compression strain of active layer 14 increases. For this reason, it is possible to suppress an accumulation of compression strain in the vicinity of active layer 14 by disposing p-side guide layer 14g substantially lattice-matched with the GaAs substrate above p-side barrier layer 14f. Furthermore, in this case, since potential energy between the ground levels for heavy holes and light holes increases, it is possible to reduce the probability of recombination between the light holes and the electrons. Accordingly, since it is possible to decrease the intensity of TM polarized light due to the recombination between the light holes and the electrons, the polarization ratio increases.

Since the above relations are satisfied, it is possible to cause energy difference ΔEc2 between the conduction band potential energies of p-side barrier layer 14f and p-side guide layer 14g to be at least 25 meV while causing energy difference ΔEc2 between the valance band potential energies of p-side barrier layer 14f and p-side guide layer 14g to be at most 30 meV. Consequently, it is possible to control the electron overflow from well layer 14d while suppressing an increase in operating voltage.

Additionally, by causing Al composition ratio ygp1 of p-side guide layer 14g to be at least 0.2 and at most 0.4, it is possible to further highly accurately control the vertical light distribution and to reduce the loss in the waveguide while suppressing a significant decrease in light confinement factor.

### 1-4. Variation 2

Next, a semiconductor light-emitting element according to Variation 2 of the present embodiment will be described with reference to FIG. 22. FIG. 22 is a schematic diagram illustrating an outline of an energy band structure of semiconductor light-emitting element 1b according to the present variation.

As shown in FIG. 22, semiconductor light-emitting element 1b according to the present variation includes p-side intermediate layer 14e in addition to the constituent elements of semiconductor light-emitting element 1a according to Variation 1. p-side intermediate layer 14e is a semiconductor layer disposed between well layer 14d and p-side barrier layer 14f. In the present variation, p-side intermediate layer 14e is an Al_{0.27}Ga_{0.73}As film having a thickness of 3 nm. p-side intermediate layer 14e is thin enough for electrons supplied to well layer 14d to exude to a p-side barrier layer 14f side.

When an Al composition ratio of p-side intermediate layer 14e is denoted by ykp1, a composition of p-side intermediate layer 14e is represented by Al_{ykp1}Ga_{1-ykp1}As; and when an Al composition ratio and an In composition ratio of p-side barrier layer 14f are denoted by ybp1 and xbp1, respectively, ybp1≤xbp1+0.975ykp1+0.069, ybp1≥0.4×bp1+0.975ykp1+0.029, and 0.2≤ykp1≤0.4 may be satisfied.

Referring to FIG. 9 to FIG. 11, when the above relations are satisfied with regard to Al composition ratio ybp1 of p-side barrier layer 14f, energy difference ΔEc2 between conduction band potential energies of p-side barrier layer 14f and p-side intermediate layer 14e is at least 25 meV, and energy difference ΔEv2 between valance band potential energies of p-side barrier layer 14f and p-side intermediate layer 14e is at most 30 meV. Accordingly, since it is possible to reduce prevention of holes from being injected into well layer 14d, it is possible to suppress an increase in operating voltage. In addition, it is possible to control the electron overflow from well layer 14d.

Moreover, by causing the Al composition ratio of p-side intermediate layer 14e to be at least 0.2 and at most 0.4, it is possible to further highly accurately control the vertical light distribution and to reduce the loss in the waveguide while increasing the light confinement factor.

Furthermore, since it is possible to disperse compression strain forming regions in the vicinity of active layer 14 by disposing, between well layer 14d and p-side barrier layer 14f, p-side intermediate layer 14e including the AlGaAs layer substantially lattice-matched with the GaAs substrate, it is possible to suppress a decrease in crystallinity due to the concentration of the compression strain.

Additionally, since it is possible to reduce the energy difference between the valance potential energies of well layer 14d and p-side intermediate layer 14e, it is possible to suppress formation of light holes having high-order levels. Accordingly, it is possible to suppress the reduction of the polarization ratio.

### 1-5. Variation 3

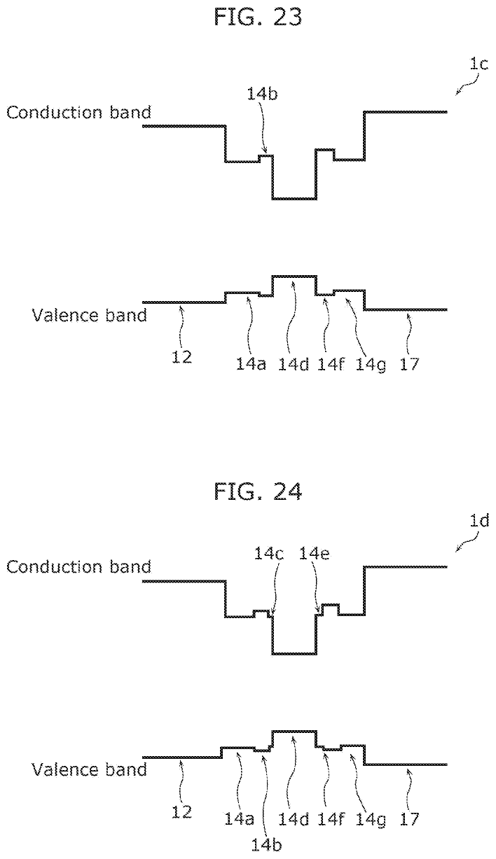

Next, a semiconductor light-emitting element according to Variation 3 of the present embodiment will be described with reference to FIG. 23. FIG. 23 is a schematic diagram illustrating an outline of an energy band structure of semiconductor light-emitting element 1c according to the present variation.

As shown in FIG. 23, semiconductor light-emitting element 1c according to the present variation includes n-side second barrier layer 14b in addition to the constituent elements of semiconductor light-emitting element 1a according to Variation 1. n-side second barrier layer 14b is a semiconductor layer disposed between n-side first barrier layer 14 and well layer 14d. In the present variation, n-side second barrier layer 14b is an Al_{0.31}Ga_{0.66}In_{0.03}As film having a thickness of 7 nm.

When an Al composition ratio and an In composition ratio of n-side second barrier layer 14b are denoted by ybn2 and xbn2, respectively, a composition of n-side second barrier layer 14b is represented by Al_{ybn2}Ga_{1-xbn2-ybn2}In_{xbn2}As, and ybn2≥xbn2+ybn1, ybn2≤0.4×bn2+0.975ybn1+0.061, xbn2≤0.15, and 0.2≤ybn1≤0.35 may be satisfied.

When the above relations are satisfied with regard to Al composition ratio ybn2 of n-side second barrier layer 14b, energy difference ΔEc2 between conduction band potential energies of n-side first barrier layer 14a and n-side second barrier layer 14b is at most 50 meV, and energy difference ΔEv2 between valance band potential energies of n-side first barrier layer 14a and n-side second barrier layer 14b is at least 30 meV. Accordingly, since it is possible to reduce prevention of holes from being injected into well layer 14d, it is possible to suppress an increase in operating voltage. In addition, it is possible to control hole overflow from well layer 14d.

Moreover, since it is possible to increase the refractive index of n-side first barrier layer 14a by causing the Al composition ratio of n-side first barrier layer 14a to be at least 0.2 and at most 0.35, the vertical light distribution is easily skewed toward the n-type semiconductor layer side. Accordingly, it is possible to reduce the loss in the waveguide.

### 1-6. Variation 4

Next, a semiconductor light-emitting element according to Variation 4 of the present embodiment will be described with reference to FIG. 24. FIG. 24 is a schematic diagram illustrating an outline of an energy band structure of semiconductor light-emitting element 1d according to the present variation.

As shown in FIG. 24, semiconductor light-emitting element 1d according to the present variation further includes p-side intermediate layer 14e and n-side third barrier layer 14c in addition to the constituent elements of semiconductor light-emitting element 1c according to Variation 3. n-side third barrier layer 14c is a semiconductor layer disposed between well layer 14d and n-side second barrier layer 14b. In the present variation, n-side third barrier layer 14c is an Al_{0.27}Ga_{0.73}As film having a thickness of 3 nm. n-side third barrier layer 14c is thin enough for electrons supplied to well layer 14d to exude to an n-side second barrier layer 14b side.

When an Al composition ratio of n-side third barrier layer 14c is denoted by ybn3, a composition of n-side third barrier layer 14c is represented by Al_{ybn3}Ga_{1-ybn3}As. Here, when an Al composition ratio and an In composition ratio of n-side second barrier layer 14b are denoted by ybn2 and xbn2, respectively, ybn2≥xbn2+ybn3, ybn2≤0.4×bn2+0.975ybn3+0.061, and 0.2≤ybn3≤0.35 may be satisfied.

When the above relations are satisfied with regard to Al composition ratio ybn2 of n-side second barrier layer 14b, energy difference ΔEc2 between conduction band potential energies of n-side second barrier layer 14b and n-side third barrier layer 14c is at most 50 meV. In addition, by causing the Al composition ratio of n-side third barrier layer 14c to be at most 0.35, it is possible to reduce the band gap energy of n-side third barrier layer 14c. Accordingly, since it is possible to reduce prevention of electrons from being injected into well layer 14d, it is possible to suppress an increase in operating voltage.

Moreover, when the above relations are satisfied with regard to Al composition ratio ybn2 of n-side second barrier layer 14b, energy difference ΔEv2 between valance band potential energies of n-side second barrier layer 14b and n-side third barrier layer 14c is at least 0 meV. In consequence, it is possible to control hole overflow from well layer 14d.

Furthermore, since it is possible to increase a refractive index of n-side third barrier layer 14c by causing the Al composition ratio of n-side third barrier layer 14c to be at least 0.2 and at most 0.35, the vertical light distribution is easily skewed toward the n-type semiconductor layer side. Accordingly, it is possible to reduce the loss in the waveguide.

### 1-7. Variation 5

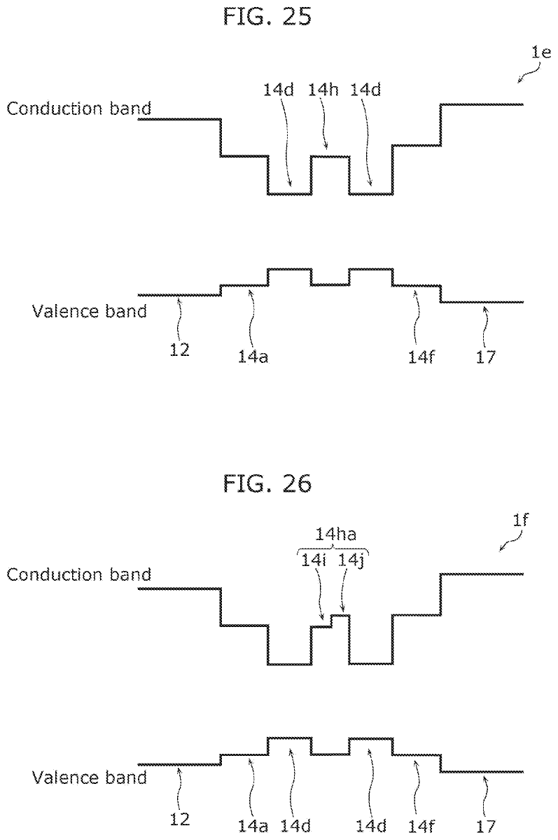

Next, a semiconductor light-emitting element according to Variation 5 of the present embodiment will be described with reference to FIG. 25. FIG. 25 is a schematic diagram illustrating an outline of an energy band structure of semiconductor light-emitting element 1e according to the present variation.

As shown in FIG. 25, semiconductor light-emitting element 1e according to the present variation has a multiple quantum well structure. An active layer of semiconductor light-emitting element 1e includes n-side first barrier layer 14a, first middle barrier layer 14h, p-side barrier layer 14f, and two well layers 14d.

First middle barrier layer 14h is disposed between n-side first barrier layer 14a and p-side barrier layer 14f. In the present variation, first middle barrier layer 14h is an Al_{0.3}Ga_{0.7}As film having a thickness of 5 nm.

One of two well layers 14d is an example of a first well layer disposed between n-side first barrier layer 14a and first middle barrier layer 14h. The other of two well layers 14d is an example of a second well layer disposed between first middle barrier layer 14h and p-side barrier layer 14f. In the present variation, each of two well layers 14d is an Al_{0.08}Ga_{0.67}In_{0.25}As film having a thickness of 6 nm.

Semiconductor light-emitting element 1e having the multiple quantum well structure as described in the present variation makes it possible to control electron overflow in p-side barrier layer 14f while suppressing an increase in operating voltage.

It should be noted that although semiconductor light-emitting element 1e according to the present variation includes two well layers 14d, the number of well layers 14d is not limited to two. The number of well layers 14d may be at least three. When semiconductor light-emitting element 1e includes N well layers 14d, semiconductor light-emitting element 1e includes (N−1) middle barrier layers from the first middle barrier layer to the (N−1)-th middle barrier layer, N being an integer greater than or equal to 2. Here, when an Al composition ratio and an In composition ratio of the k-th (k=1, 2, 3, . . . N−1) middle barrier layer are denoted by ybk and xbk (k=1, 2, 3, . . . N−1), respectively, a composition of the k-th middle barrier layer is represented by Al_{ybk}Ga_{1-xbk-ybk}In_{xbk}As. Here, ybn1≤ybk≤ybp1 and xbn1≤xbk≤xbp1 are satisfied, and the k-th middle barrier layer has a band gap energy that is larger than or equal to a band gap energy of n-side first barrier layer 14a and is smaller than or equal to a band gap energy of p-side barrier layer 14f.

Accordingly, it is possible to produce the same effects as semiconductor light-emitting element 1 according to the present embodiment. Moreover, since it is possible to reduce an operating carrier density in a laser oscillation state in each well layer using the multiple quantum well structure, it is possible to further control the electron overflow. For this reason, temperature characteristics of semiconductor light-emitting element 1e are further improved.

### 1-8. Variation 6

Next, a semiconductor light-emitting element according to Variation 6 of the present embodiment will be described with reference to FIG. 26. FIG. 26 is a schematic diagram illustrating an outline of an energy band structure of semiconductor light-emitting element if according to the present variation.

As shown in FIG. 26, semiconductor light-emitting element if according to the present variation has a multiple quantum well structure. An active layer of semiconductor light-emitting element if includes n-side first barrier layer 14a, first middle barrier layer 14ha, p-side barrier layer 14f, and two well layers 14d.

As with first middle barrier layer 14h according to Variation 5, first middle barrier layer 14ha according to the present variation is disposed between n-side first barrier layer 14a and p-side barrier layer 14f. In the present variation, first middle barrier layer 14ha includes first middle n-side barrier layer 14i and first middle p-side barrier layer 14j.

First middle n-side barrier layer 14i of first middle barrier layer 14ha is disposed on an n-side first barrier layer 14a side. In In the present variation, first middle n-side barrier layer 14i is an Al_{0.3}Ga_{0.7}As film having a thickness of 3 nm.

First middle p-side barrier layer 14j of first middle barrier layer 14ha is disposed on the p-side barrier layer 14f side. In In the present variation, first middle p-side barrier layer 14j is an Al_{0.45}Ga_{0.45}As film having a thickness of 3 nm.

One of two well layers 14d is an example of a first well layer disposed between n-side first barrier layer 14a and first middle barrier layer 14ha. The other of two well layers 14d is an example of a second well layer disposed between first middle barrier layer 14ha and p-side barrier layer 14f. In the present variation, each of two well layers 14d is an Al_{0.08}Ga_{0.67}In_{0.25}As film having a thickness of 6 nm.

Semiconductor light-emitting element if having the multiple quantum well structure as described in the present variation makes it possible to control electron overflow in p-side barrier layer 14f while suppressing an increase in operating voltage.

It should be noted that although semiconductor light-emitting element if according to the present variation includes two well layers 14d, the number of well layers 14d is not limited to two. The number of well layers 14d may be at least three. When semiconductor light-emitting element if includes N well layers 14d, semiconductor light-emitting element if includes (N−1) middle barrier layers from the first middle barrier layer to the (N−1)-th middle barrier layer, N being an integer greater than or equal to 2. In addition, the k-th (k=1, 2, 3, . . . , N−1) middle barrier layer includes the k-th middle n-side barrier layer and the k-th middle p-side barrier layer. When Al composition ratios and In composition ratios of the k-th middle n-side barrier layer and the k-th middle p-side barrier layer (k=1, 2, 3, . . . N−1) are denoted by ybck, ybk, xbck, and xbk (k=1, 2, 3, . . . N−1), respectively, compositions of the k-th middle n-side barrier layer and the k-th middle p-side barrier layer are represented by Al_{ybck}Ga_{1-xbck-ybck}In_{xbck}As and Al_{ybk}Ga_{1-xbk-ybk}In_{xbk}As, respectively. Here, ybn1≤ybk≤ybp1, xbn1≤xbk≤xbp1, and ybn1≤ybck≤ybp1 are satisfied, the k-th middle n-side barrier layer has a band gap energy smaller than or equal to a band gap energy of the k-th middle p-side barrier layer, and the k-th middle p-side barrier layer has the band gap energy smaller than or equal to a band gap energy of p-side barrier layer 14f.

Accordingly, it is possible to produce the same effects as semiconductor light-emitting element 1e according to Variation 5.

Moreover, ybp1≤xbp1+0.975ybck+0.069, ybp1≥0.4×bp1+0.975ybck+0.029, and 0.2≤ybck≤0.4 may be satisfied.

Accordingly, the k-th middle barrier layer makes it possible to cause a conduction band potential energy to be larger in the k-th middle n-side barrier layer than in the k-th middle p-side barrier layer while suppressing a valance band potential energy difference between the k-th middle n-side barrier layer and the k-th middle p-side barrier layer. As a result, it is possible to control the electron overflow from each well layer 14d without degrading electrical conductivity of holes between two adjacent well layers 14d.

For this reason, when ybn1, xbn1, ybp1, xbp1, ybk, and ybck are within the above ranges, it is possible not only to reduce an operating carrier density in a laser oscillation state in well layer 14d using the multiple quantum well structure according to the present variation while producing the same effects as semiconductor light-emitting element 1e according to Variation 5, but also to control the electron overflow and to improve the temperature characteristics.

### 1-9. Variation 7

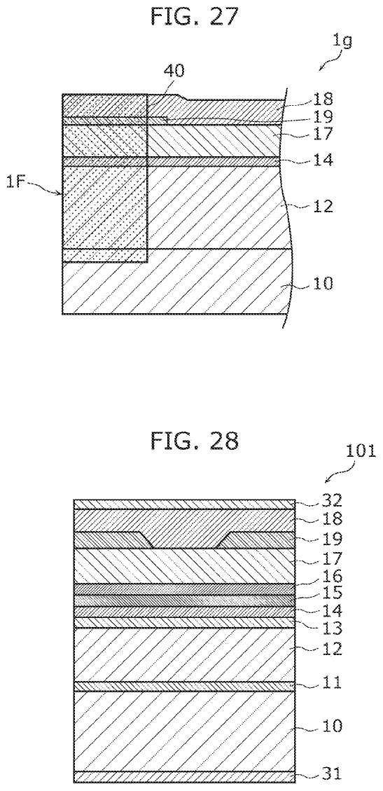

Next, a semiconductor light-emitting element according to Variation 7 of the present embodiment will be described with reference to FIG. 27. FIG. 27 a cross-sectional view illustrating a configuration of light-emitting end face portion 40 of semiconductor light-emitting element 1g according to the present variation. FIG. 27 shows a portion of a cross section of semiconductor light-emitting element 1g according to the present variation that is parallel to a resonance direction of laser light and perpendicular to the principal surface of substrate 10.

Semiconductor light-emitting element 1g according to the present variation differs from semiconductor light-emitting element 1 according to Embodiment 1 in that light-emitting end face portion 40 has what is called a window mirror structure, but otherwise is the same as semiconductor light-emitting element 1 according to Embodiment 1. It should be noted that n-side electrode 31 and p-side electrode 32 are omitted from FIG. 27. It should be noted that light-emitting end face portion 40 is a region including light-emitting end face 1F of semiconductor light-emitting element 1g. It should be noted that, in semiconductor light-emitting element 1g, not only light-emitting end face portion 40 but also a rear side end face portion (a region including an end face opposite to light-emitting end face 1F) may have a window mirror structure. A region taken up by the rear side end face portion is not particularly limited, but the rear side end face portion includes, for example, a region having at least 1% of a resonator length from a rear side end face in the resonance direction.

Specifically, vacancies or impurities are diffused into light-emitting end face portion 40 of active layer 14 of semiconductor light-emitting element 1g according to the present variation. Hereinafter, the window mirror structure according to the present variation will be described in detail.

Among AlAs, GaAs, and InAs, InAs has the largest lattice constant and the smallest band gap energy. As with semiconductor light-emitting element 1g according to the present variation, when a desired band gap energy is obtained by using an AlGaInAs-based quaternary semiconductor material for well layer 14d and each barrier layer, an In content rate of well layer 14d including AlGaInAs increases, which increases a compression strain of well layer 14d, compared to when a desired band gap energy is obtained by using a semiconductor material including InGaAs for well layer 14d.

As seen from the above, when vacancies or impurities are diffused into light-emitting end face portion 40 of semiconductor light-emitting element 1g in the structure in which the AlGaInAs-based quaternary semiconductor material is used for well layer 14d and each barrier layer, since a strain energy of well layer 14d is reduced, the In atoms of well layer 14d are easily exchanged with the Al atoms and Ga atoms in group-III lattice positions relative to the stacked direction. Accordingly, a band gap energy of well layer 14d easily increases.

As a result, the band gap energy of well layer 14d increases in light-emitting end face portion 40 having a high light density, and it is possible to form what is called a window structure. In other words, a portion of active layer 14 in which the window mirror structure is formed has a band gap energy larger than a band gap energy of a portion of active layer 14 in which the window mirror structure is not formed. For this reason, even when a band gap energy of light-emitting end face portion 40 is reduced due to heat generation, it is possible to maintain the light absorption by light-emitting end face portion 40 in well layer 14d at a low level. Accordingly, it is possible to suppress the occurrence of COD due to the light absorption by light-emitting end face portion 40.

When a length of the window structure in the resonance direction is denoted by Lw, a distance between a resonator end face portion and a region (a gain region) having no window structure increases with an increase in Lw. The gain region is a region in which active layer 14 emits light. Radiative recombination and non-radiative recombination occur in active layer 14 due to current injection into the gain region.

A temperature of active layer 14 is increased not only by Joule heating in a series resistance component included in semiconductor light-emitting element 1g but also by heat generation associated with the non-radiative recombination. Since the resonator end face portion is formed by cleavage at the time of manufacturing a resonator, a crystal defect level easily occurs. Since a band gap energy of the resonator end face portion is further reduced when semiconductor light-emitting element 1g generates heat, light absorption by the resonator end face portion at the crystal defect level further increases, which easily causes COD.

Increasing Lw increases the distance between the gain region and the resonator end face portion and reduces the influence of heat generation by the gain region on the resonator end face portion, which is advantageous to suppress the occurrence of the COD. However, since excessively increasing Lw shortens the length of the gain region, current crowding in the gain region increases. Concomitantly, since electron overflow from active layer 14 increases, temperature characteristics are deteriorated.

On the other hand, when the AlGaInAs-based quaternary semiconductor material is used for well layer 14d and each barrier layer as stated above, the In atoms of well layer 14d are easily exchanged with the Al atoms and Ga atoms in the group-III lattice positions relative to the stacked direction, and a band gap energy of well layer 14d easily increases. When a band gap energy of active layer 14 in a window structure region increases, laser light absorption in the window structure region is reduced and so is heat generation in the window structure region. For this reason, in semiconductor light-emitting element 1g according to the present variation, the influence of the heat generation in the gain region on the resonator end face portion is reduced even when Lw is decreased, and it is possible to decrease Lw, compared to a structure in which InGaAs and AlGaAs are used for conventional well layer 14d and each barrier layer, respectively. Specifically, although Lw is conventionally required to be at least 30 μm, when the AlGaInAs-based quaternary semiconductor material is used for well layer 14d and each barrier layer, it is possible to suppress the occurrence of the COD as long as Lw is at least 15 μm.

Additionally, when the window structure is formed by vacancy diffusion, it is possible to suppress the occurrence of a free carrier loss due to the presence of impurities, and thus it is possible to suppress a decrease in slope efficiency, compared to a case in which the window structure is formed by impurity diffusion.

### Embodiment 2

A semiconductor light-emitting element according to Embodiment 2 will be described. The semiconductor light-emitting element according to the present embodiment differs from semiconductor light-emitting element 1 according to Embodiment 1 in further including an n-side guide layer between active layer 14 and n-type clad layer 12, for example. Hereinafter, the semiconductor light-emitting element according to the present embodiment will be described with reference to FIG. 28, focusing mainly on the differences from semiconductor light-emitting element 1 according to Embodiment 1.

FIG. 28 is a cross-sectional view schematically illustrating an entire configuration of semiconductor light-emitting element 101 according to the present embodiment. As shown in FIG. 28, semiconductor light-emitting element 101 according to the present embodiment includes n-side guide layer 13, first strain control layer 15, and second strain control layer 16 in addition to the constituent elements of semiconductor light-emitting element 1 according to Embodiment 1.

n-side guide layer 13 is an n-type semiconductor layer disposed between n-type clad layer 12 and active layer 14. n-side guide layer 13 has a higher refractive index than n-type clad layer 12 does. For this reason, it is possible to move a vertical light distribution closer to active layer 14 than semiconductor light-emitting element 1 according to Embodiment 1 does. As a result, it is possible to suppress a decrease in light confinement factor for confining light to active layer 14. In the present embodiment, a refractive index of n-side guide layer 13 is increased by causing an Al composition ratio of n-side guide layer 13 to be lower than an Al composition ratio of n-type clad layer 12. In addition, n-side guide layer 13 contains n-type impurities, and a region of n-side guide layer 13 on the n-type clad layer 12 side has a lower impurity concentration than a region of n-side guide layer 13 on an active layer 14 side does. Accordingly, it is possible to reduce a waveguide loss due to the impurities in n-side guide layer 13 while suppressing a degradation of electrical conductivity of n-side guide layer 13. Specifically, n-side guide layer 13 is an Al_{0.27}Ga_{0.73}As layer having a thickness of 1 μm. Moreover, a portion of n-side guide layer 13 that is 0.25 μm thick and on the active layer 14 side is doped with Si having a concentration of 5×10¹⁷ cm⁻³, and a portion of n-side guide layer 13 that is 0.75 μm thick and on the n-type clad layer 12 side is doped with Si having a concentration of 5×10¹⁶ cm⁻³. The impurity concentration of n-side guide layer 13 is not particularly limited, but the portion of n-side guide layer 13 on the n-type clad layer 12 side may have, for example, an impurity concentration of at most 1×10¹⁷ cm⁻³ in order to reduce the waveguide loss in n-side guide layer 13. Additionally, an impurity concentration of the portion of n-side guide layer 13 on the active layer 14 side may be higher than, for example, 1×10¹⁷ cm⁻³ in order to prevent the electrical conductivity of n-side guide layer 13 from being degraded.

First strain control layer 15 is a semiconductor layer disposed between active layer 14 and p-type clad layer 17 and containing Al. In the present embodiment, first strain control layer 15 is an Al_{0.70}Ga_{0.30}As layer having a thickness of 0.05 μm.

Second strain control layer 16 is a semiconductor layer disposed between first strain control layer 15 and p-type clad layer 17 and having a lower composition ratio and a lower Young's modulus than first strain control layer 15 does. In the present embodiment, second strain control layer 16 is an Al_{0.30}Ga_{0.70}As layer having a thickness of 0.16 μm.

First strain control layer 15 and second strain control layer 16 have, for example, an impurity concentration of at least 2×10¹⁷ cm⁻³ and at most 6×10¹⁷ cm⁻³. In the present embodiment, first strain control layer 15 and second strain control layer 16 are doped with C having a concentration of 3×10¹⁷ cm⁻³.

First strain control layer 15 and second strain control layer 16 are for reducing the influence of a mounting strain on active layer 14 when semiconductor light-emitting element 101 is junction down mounted (i.e., when p-side electrode 32 is connected to a mounting surface). When semiconductor light-emitting element 101 according to the present embodiment is junction down mounted, second strain control layer 16 having a low Young's modulus absorbs most of stress due to the mounting strain. As a result, second strain control layer 16 makes it possible to prevent the stress due to the mounting strain from being added to active layer 14 disposed in a position away from the mounting surface. For this reason, it is possible to cause the strain in active layer 14 to stably have the same magnitude as a strain determined based on crystal growth. Concomitantly, since band structure controllability after semiconductor light-emitting element 101 is mounted is improved, a stable high-temperature high-power operation is made possible. Accordingly, the present embodiment makes it possible to stably achieve a semiconductor laser element that has excellent temperature characteristics and a high slope efficiency and is suitable for a high-temperature high-power operation.

### Embodiment 3

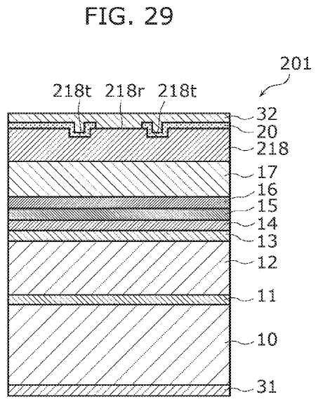

A semiconductor light-emitting element according to Embodiment 3 will be described. The semiconductor light-emitting element according to the present embodiment differs from semiconductor light-emitting element 101 according to Embodiment 2 in that a p-type semiconductor layer includes a ridge portion. Hereinafter, the semiconductor light-emitting element according to the present embodiment will be described with reference to FIG. 29, focusing mainly on the differences from semiconductor light-emitting element 101 according to Embodiment 2.

FIG. 29 is a cross-sectional view schematically illustrating an entire configuration of semiconductor light-emitting element 201 according to the present embodiment. As shown in FIG. 29, semiconductor light-emitting element 201 according to the present embodiment includes substrate 10, buffer layer 11, n-type clad layer 12, n-side guide layer 13, active layer 14, first strain control layer 15, second strain control layer 16, p-type clad layer 17, contact layer 218, current blocking layer 20, n-side electrode 31, and p-side electrode 32.

Although contact layer 218 according to the present embodiment has the same composition as contact layer 18 according to Embodiment 2, contact layer 218 differs from contact layer 18 in including ridge portion 218r. Two grooves 218t extending in a resonance direction of laser light are formed on a top face (i.e., a face on a p-side electrode 32 side) of contact layer 218, and ridge portion 218r is formed between two grooves 218t. In the present embodiment, current is concentratively confined to ridge portion 218r, and a waveguide is formed along ridge portion 218r.

Current blocking layer 20 is an insulating layer for concentrating current on ridge portion 218r. Current blocking layer 20 is disposed in a region on contact layer 218 other than ridge portion 218r. In the present embodiment, current blocking layer 20 is disposed on contact layer 218, in a region other than a top face of ridge portion 218r. Stated differently, a slit extending in the resonance direction of laser light is formed above ridge portion 218r in current blocking layer 20. Although current blocking layer 20 is not particularly limited as long as current blocking layer 20 is an insulating film, current blocking layer 20 is an SiO₂ film having a thickness of 0.02 μm in the present embodiment.

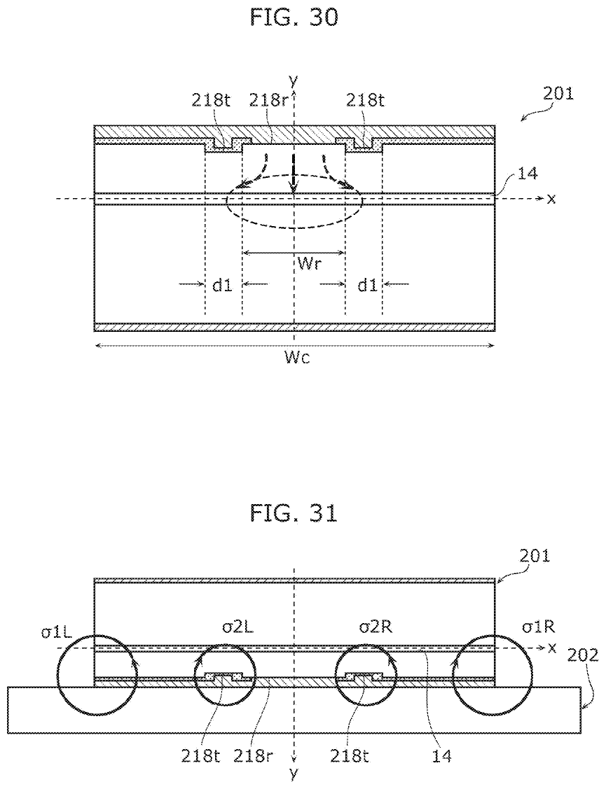

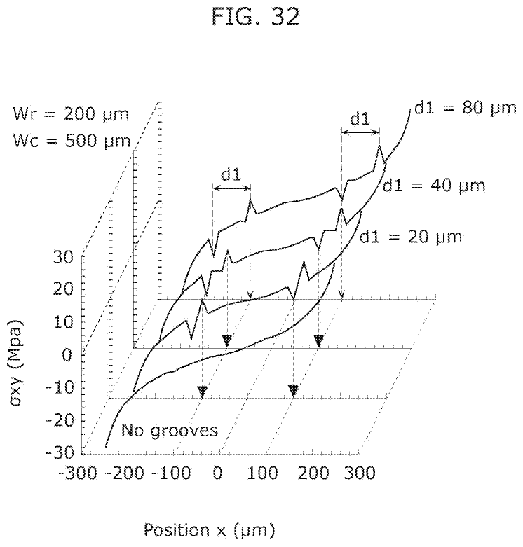

Next, functions and effects of semiconductor light-emitting element 201 according to the present embodiment will be described with reference to FIG. 30 to FIG. 32. FIG. 30 is a cross-sectional view schematically illustrating a size of each part of semiconductor light-emitting element 201 according to the present embodiment. FIG. 31 is a cross-sectional view schematically illustrating a mounted state of semiconductor light-emitting element 201 according to the present embodiment. FIG. 32 is a graph showing a distribution of shear stress σxy relative to a position of active layer 14 of semiconductor light-emitting element 201 according to the present embodiment in the x-axis direction.

As shown in FIG. 30, a stacked direction of each layer of semiconductor light-emitting element 201 (i.e., a direction perpendicular to the principal surface of substrate 10) is the y-axis direction. Moreover, a direction perpendicular to the resonance direction of laser light and the y-axis direction is the x-axis direction. Furthermore, as shown in FIG. 30, a width of each of two grooves 218t in the x-axis direction is denoted by d1, and a width of ridge portion 218r in the x-axis direction is denoted by Wr. In addition, a width of semiconductor light-emitting element 201 in the x-axis direction is denoted by Wc.

The following describes stress added to such semiconductor light-emitting element 201 when semiconductor light-emitting element 201 is junction down mounted on submount 202 as shown in FIG. 31.

Submount 202 is, for example, a plate-like component formed of Cu.

Here, a thermal expansion coefficient of semiconductor light-emitting element 201 is substantially the same as a thermal expansion coefficient (5.35×10⁻⁶K⁻¹) of GaAs, and is lower than a thermal expansion coefficient (16.8×10⁻⁶K⁻¹) of submount 202. When semiconductor light-emitting element 201 is junction down mounted on such submount 202, a shear stress corresponding to a difference between the thermal expansion coefficients of semiconductor light-emitting element 201 and submount 202 is applied to active layer 14 of semiconductor light-emitting element 201. In this case, semiconductor light-emitting element 201 receives a stress compressive in the x-axis direction from submount 202. Specifically, as shown in FIG. 31, clockwise shear stress σ1R and counterclockwise shear stress σ1L are added to a right end portion and a left end portion of semiconductor light-emitting element 201 in the x-axis direction, respectively. Additionally, counterclockwise shear stress σ2R and clockwise shear stress σ2L are added to a right end portion and a left end portion of ridge portion 218r, respectively. As stated above, the shear stress symmetrical about the center of ridge portion 218r in the x-axis direction is added to semiconductor light-emitting element 201.

The following describes the shear stress added to semiconductor light-emitting element 201 with reference to FIG. 31 and FIG. 32. FIG. 32 shows a distribution of shear stress in the x-axis direction when width Wc of semiconductor light-emitting element 201 in the x-axis direction is 500 μm, and width Wr of ridge portion 218r in the x-axis direction is 200 μm. It should be noted that FIG. 32 shows calculation results when width d1 of groove 218t is 20 μm, 40 μm, and 80 μm. Additionally, FIG. 32 shows a shear stress calculation result when groove 218t is absent.

As shown in FIG. 31, for example, since shear stress σ2R due to groove 218t and shear stress σ2L due to the right end portion of semiconductor light-emitting element 201 in the x-axis direction have opposite orientations, the shear stress is reduced in the right end portion of ridge portion 218r in the x-axis direction (see position x in FIG. 32 indicating 100 μm). As with the right end portion of ridge portion 218r, the shear stress is reduced in the left end portion of ridge portion 218r in the x-axis direction (see position x in FIG. 32 indicating−100 μm).

As shown by thick dashed arrows in FIG. 30, current reaches active layer 14 from ridge portion 218r while spreading in the x-axis direction in semiconductor light-emitting element 201. For this reason, since laser light in semiconductor light-emitting element 201 is distributed to a region corresponding to positions of grooves 218t in the x-axis direction in active layer 14, the laser light is subject to the influence of shear stress of grooves 218t. It should be noted that a dashed circle shown in FIG. 30 indicates an outer edge of the laser light distribution region. Moreover, if the shear stress distribution in active layer 14 is not completely symmetrical about the center of ridge portion 218r in the x-axis direction, since a correlation integral between the light distribution and the shear stress is not 0 when birefringence occurs in semiconductor light-emitting element 201 due to the shear stress, a polarization plane is inclined. It should be noted that a correlation integral between a shear stress and a light distribution is expressed by the following equation.

∫∫σ_{xy}|Φ|²dxdy|Φ|²:Light distribution [Math. 1]

In the present embodiment, forming grooves 218t makes it possible to reduce the shear stress in the end portions of ridge portion 218r, it is possible to reduce the influence of the shear stress on the light distribution. Accordingly, semiconductor light-emitting element 201 according to the present embodiment makes it possible to suppress a decrease in polarization ratio due to the polarization plane being inclined when an asymmetrical strain occurs in the middle of semiconductor light-emitting element 201 in the x-axis direction. For example, it is possible to reduce the shear stress in the vicinity of the end portions of ridge portion 218r in the x-axis direction by causing width d1 of groove 218t in the x-axis direction to be at least 10 μm. On the other hand, since a load is concentrated in ridge portion 218r at the time of junction down mounting if width d1 of groove 218t is excessively increased, width d1 of groove 218t may be at most 40 μm.

Moreover, with regard to a depth of groove 218t, when a step (i.e., a portion in which a bottom face and a side face of groove 218t are joined) of groove 218t is brought too close to active layer 14, the shear stress occurring in active layer 14 due to the influence of the irregularities increases, and a polarization ratio is reduced. For this reason, the depth of groove 218t may be at most 0.3 μm. In the present embodiment, groove 218t is formed only in contact layer 218 and has a depth of 0.2 μm.

### Embodiment 4

A semiconductor light-emitting element and a method of manufacturing the same according to Embodiment 4 will be described. The semiconductor light-emitting element according to the present embodiment differs from semiconductor light-emitting element 1c according to Variation 3 of Embodiment 1 mainly in materials used for a p-side guide layer, an n-type clad layer, and a p-type clad layer. Hereinafter, the semiconductor light-emitting element according to the present embodiment will be described focusing mainly on the differences from semiconductor light-emitting element 1c according to Variation 3 of Embodiment 1.

### 4-1. Entire Configuration

First, an entire configuration of the semiconductor light-emitting element according to the present embodiment will be described. As with semiconductor light-emitting element 1c according to Variation 3 of Embodiment 1, the semiconductor light-emitting element according to the present embodiment includes a substrate, an n-type clad layer, an active layer, a p-type clad layer, a current confinement layer, a contact layer, an n-side electrode, and a p-side electrode. The semiconductor light-emitting element according to the present embodiment further includes an n-side guide layer disposed between the n-type clad layer and the active layer.

The semiconductor light-emitting element according to the present embodiment differs from semiconductor light-emitting element 1c in a material used for each layer. The following describes, among the layers included in the semiconductor light-emitting element according to the present embodiment, layers and the n-side guide layer for each of which a material different from the material of each layer included in semiconductor light-emitting element 1c is used.

When an Al composition ratio of the n-type clad layer is denoted by yn2, a composition of the n-type clad layer is represented by (Al_{yn2}Ga_{1-yn2})_{0.5}In_{0.5}P. It should be noted that the In composition ratio (and the composition ratio of (Al_{yn2}Ga_{1-yn2})) in (Al_{yn2}Ga_{1-yn2})_{0.5}In_{0.5}P means a composition ratio in a range in which a hundredths-place digit is rounded to 0.5. Each of other composition ratios represented by a decimal is not limited to only one value and means a composition ratio in a range in which a value lower than the decimal is rounded to a decimal. By causing the composition of the n-type clad layer to be (Al_{yn2}Ga_{1-yn2})_{0.5}In_{0.5}P, vacancies or impurities such as Zn and Mg are easily diffused in the n-type clad layer. Accordingly, it is possible to reduce the time needed to form a window mirror structure by diffusing vacancies or impurities into the semiconductor light-emitting element. Moreover, since it is possible to decrease an impurity concentration used when the impurities are diffused, it is possible to reduce the light absorption by the impurities. Consequently, it is possible to suppress a decrease in luminous efficiency of the semiconductor light-emitting element.

In order to cause a strain of the n-type clad layer formed on the substrate including n-type GaAs to be at most ±0.2%, when the Al composition ratio is at least 0 and at most 0.6, the In composition ratio may be at least 0.45 and at most 0.513. In the present embodiment, the n-type clad layer is an n-type (Al_{0.14}Ga_{0.86})_{0.5}In_{0.5}P layer having a thickness of 3.5 μm. The n-type clad layer includes portions each doped with impurities having a different concentration. The n-type clad layer includes, in order from an end face close to the substrate, a portion that is 2.5 μm thick and doped with Si having a concentration of 1×10¹⁸ cm⁻³, a portion that is 0.5 μm thick and doped with Si having a concentration of 5×10¹⁷ cm⁻³, and a portion that is 0.5 μm thick and doped with Si having a concentration of 2×10¹⁷ cm⁻³.

The n-side guide layer is disposed between the n-type clad layer and the active layer. In the present embodiment, the n-type guide layer is an n-type (Al_{0.04}Ga_{0.96})_{0.5}In_{0.5}P layer having a thickness of 0.5 μm. The n-side guide layer is doped with Si having a concentration of 1×10¹⁷ cm⁻³.

The active layer includes an n-side first barrier layer, an n-side second barrier layer, a well layer, a p-side barrier layer, and a p-side guide layer. In the present embodiment, the n-side first barrier layer is an undoped Al_{0.5}Ga_{0.5}As layer having a thickness of 14 nm. The n-side second barrier layer is an undoped Al_{0.55}Ga_{0.45}As layer having a thickness of 3.5 nm. The well layer is an undoped In_{0.08}Ga_{0.92}As layer having a thickness of 6 nm. The p-side barrier layer is an undoped Al_{0.5}Ga_{0.16}In_{0.25}As layer having a thickness of 3.5 nm.

When an Al composition ratio of the p-side guide layer is denoted by ygp2, a composition of the p-side guide layer is represented by (Al_{ygp2}Ga_{1-gp2})_{0.5}In_{0.5}P. By causing the composition of the p-side guide layer to be (Al_{ygp2}Ga_{1-gp2})_{0.5}In_{0.5}P, vacancies or impurities such as Zn and Mg are easily diffused in the p-side guide layer. Accordingly, the same effects as the above-described n-type clad are produced. In the present embodiment, the p-side guide layer is a p-type (Al_{0.04}Ga_{0.96})_{0.5}In_{0.5}P layer having a thickness of 220 nm. The p-side guide layer is doped with C having a concentration of 1×10¹⁷ cm⁻³.

When an Al composition ratio of the p-type clad layer is denoted by yp2, a composition of the p-type clad layer is represented by (Al_{yp2}Ga_{1-yp2})_{0.5}In_{0.5}P. By causing the composition of the p-type clad layer to be (Al_{yp2}Ga_{1-yp2})_{0.5}In_{0.5}P, vacancies or impurities such as Zn and Mg are easily diffused in the p-type clad layer. Accordingly, the same effects as the above-described n-type clad are produced. In the present embodiment, the p-type clad layer is a p-type (Al_{0.6}Ga_{0.4})_{0.5}In_{0.5}P layer having a thickness of 0.8 μm. The p-type clad layer is doped with C having a concentration of 2×10¹⁸ cm⁻³.

In the present embodiment, with regard to Al composition ratio yn2 of the n-type clad layer and Al composition ration yp2 of the p-type clad layer, 0<yn2<yp2<1 is satisfied. As a result, the p-type clad layer has a lower refractive index than the n-type clad layer does. For this reason, it is possible to skew a laser light intensity distribution toward an n-type clad layer side. In other words, since it is possible to reduce laser light propagating through the p-type clad layer, it is possible to reduce a free carrier loss due to the impurities in the p-type clad layer. Accordingly, it is possible to reduce a loss in a waveguide.

### 4-2. Manufacturing Method

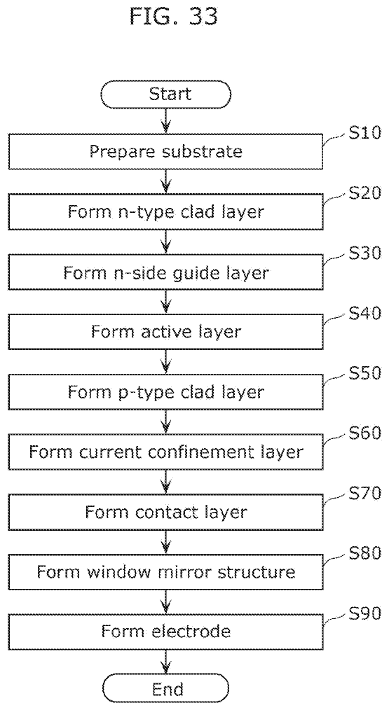

Next, a semiconductor light-emitting element manufacturing method according to the present embodiment will be described with reference to FIG. 33. FIG. 33 is a flow chart illustrating steps of the semiconductor light-emitting element method according to the present embodiment.

As shown in FIG. 33, first, a substrate is prepared (S10). In the present embodiment, an n-type GaAs substrate is prepared.

Next, an n-type clad layer is formed above the substrate (S20). In the present embodiment, an n-type (Al_{yn2}Ga_{1yn2})_{0.5}In_{0.5}P layer is formed as the n-type clad layer on a top face of the substrate.

Then, an n-side guide layer is formed above the n-type clad layer (S30). In the present embodiment, an n-type (Al_{0.04}Ga_{0.96})_{0.5}In_{0.5}P layer is formed as the n-side guide layer on a top face of the n-type clad layer.

After that, an active layer is formed above the n-side guide layer (S40). In the present embodiment, an n-side first barrier layer, an n-side second barrier layer, a well layer, a p-side barrier layer, and a p-side guide layer are formed as the active layer on a top face of the n-side guide layer, in stated order. Specifically, an undoped Al_{0.5}Ga_{0.5}As layer is formed as the n-side first barrier layer, an undoped Al_{0.55}Ga_{0.45}As layer is formed as the n-side second barrier layer, an undoped In_{0.08}Ga_{0.92}As layer is formed as the well layer, an undoped Al_{0.59}Ga_{0.16}In_{0.25}As layer is formed as the p-side barrier layer, and a p-type (Al_{ygp2}Ga_{1-gyp2})_{0.5}In_{0.5}P layer is formed as the p-side guide layer.

Next, a p-type clad layer is formed above the active layer (S50). In the present embodiment, a p-type (Al_{yp2}Ga_{1-yp2})_{0.5}In_{0.5}P layer is formed as the p-type clad layer on a top face of the active layer.

Then, a current confinement layer is formed above the p-type clad layer (S60). In the present embodiment, an n-type GaAs layer is formed as the current confinement layer on a top face of the p-type clad layer, and an opening elongated in a laser resonance direction is formed by, for example, photolithography and etching.

After that, a contact layer is formed above the current confinement layer (S70). In the present embodiment, a p-type GaAs layer is formed as the contact layer on a top face of the current confinement layer and the opening.

Each of the above-described semiconductor layers is formed by, for example, metalorganic chemical vapor deposition (MOCVD).

Next, a window mirror structure is formed in the active layer (S80). Specifically, vacancies or impurities are diffused into a light-emitting end face portion of the active layer from a top face of the contact layer. By diffusing the vacancies or the impurities as above, it is possible to disorder a quantum well structure in the light-emitting end face portion of the active layer. Concomitantly, it is possible to increase a band gap energy of the active layer. To put it another way, it is possible to form a window structure. In the present embodiment, since the n-type (Al_{yn2}Ga_{1-yn2})_{0.5}In_{0.5}P layer, the p-type (Al_{ygp2}Ga_{1-gp2})_{0.5}In_{0.5}P layer, and the p-type (Al_{yp2}Ga_{1-yp2})_{0.5}In_{0.5}P layer are formed as the n-type clad layer, the p-side guide layer, and the p-type clad layer, respectively, vacancies or impurities are easily diffused. Accordingly, it is possible to reduce the time needed to form the window mirror structure. Moreover, since it is possible to decrease an impurity concentration used when the impurities are diffused, it is possible to reduce the light absorption by the impurities. Consequently, it is possible to suppress a decrease in luminous efficiency of the semiconductor light-emitting element. It should be noted that the window mirror structure may be formed not only in the light-emitting end face portion but also in both end face portions forming a resonator of the semiconductor light-emitting element.

Finally, electrodes are formed (S90). Specifically, a p-side electrode is formed on the top face of the contact layer, and an n-side electrode is formed on a lower principal surface of the substrate. In the present embodiment, a Ti film, a Pt film, and an Au film are sequentially formed as the p-side electrode from a contact layer side, and an AuGe film, an Ni film, an Au film, a Ti film, a Pt film, a Ti film, a Pt film, and an Au film are sequentially formed as the n-side electrode from a substrate 10 side.

It is possible to manufacture the semiconductor light-emitting element according to the present embodiment as described above.

### Other Variations

Although the semiconductor light-emitting element according to the present disclosure and the method of manufacturing the same have been described above based on each of the aforementioned embodiments, the present disclosure is not limited to the embodiment.

For example, although each of the aforementioned embodiments has described the example in which the semiconductor light-emitting element is the semiconductor laser element, the semiconductor light-emitting element is not limited to the semiconductor laser element. For example, the semiconductor light-emitting element may be a superluminescent diode.

Although the AlGaInAs-based material is used for the semiconductor light-emitting element in each of the aforementioned embodiments, other semiconductor materials may be used. For example, a nitride-based semiconductor material may be used. Specifically, an AlGaInN-based material may be used. Hereinafter, the AlGaInAs-based material and the conduction band potential energy and valance band potential energy of the AlGaInN-based material will be described.

Physical properties that influence the conduction band potential energy and the valance band potential energy include electron affinity, band gap energy, and lattice strain. A lattice strain is determined by a lattice constant of a semiconductor layer and a lattice constant of a substrate on which the semiconductor layer is stacked. In the AlGaInAs-based material and the AlGaInN-based material, with regard to binary compounds (AlAs, GaAs, and InAs, and AlN, GaN, and InN) that are elements of these materials, magnitude relations of electron affinity, band gap energy, and lattice constant are as follows. An electron affinity decreases in order from InAs, GaAs, and AlAs, and decreases in order from InN, GaN, and AlN. A band gap energy decreases in order from AlAs, GaAs, and InAs, and decreases in order from AlN, GaN, and InN. Among the elements of the AlGaInAs-based material, InAs has a lattice constant larger than lattice constants of GaAs and AlAs, and GaAs has a substantially same lattice constant as AlAs. In addition, among the elements of the AlGaInN-based material, InN has a lattice constant larger than lattice constants of GaN and AlN, and GaN has a substantially same lattice constant as AlN.

It is clear from the above description that even when group V atoms of a quaternary semiconductor material are different from each other, the magnitude relations of the above-described physical properties are similar to each other.

Among AlAs, GaAs, and InAs that are the elements of the AlGaInAs-based material, InAs has the largest lattice constant and the smallest band gap energy. When a desired band gap energy is obtained by using a layer including an AlGaInAs-based quaternary semiconductor material for a well layer and a barrier layer, the In content rate of the well layer including AlGaInAs increases, which increases a compression strain of the well layer, compared to when a desired band gap energy is obtained by using a layer including InGaAs for the well layer.

Among AlN, GaN, and InN in the AlGaInN-based material, InN has the largest lattice constant and the smallest band gap energy. When a desired band gap energy is obtained by using an AlGaInN-based quaternary semiconductor material for a well layer and a barrier layer, the In content rate of the well layer including AlGaInN increases, which increases a compression strain of the well layer, compared to when a desired band gap energy is obtained by using a layer including InGaN for the well layer or a layer including AlGaN for the barrier layer.

A relation that an electron affinity increases with a higher In content rate and decreases with a higher Al content rate is applied to both the AlGaInAs-based material and the AlGaInN-based material.

For this reason, when the AlGaInAs-based material is used for the barrier layer, and a band gap energy increases while the In composition ratio increases, a change in conduction band potential energy (ΔEbc) becomes greater than a change in valance band potential energy (ΔEbv), which is true for the AlGaInN-based material. Consequently, the AlGaInN-based quaternary semiconductor material may be used as a material included in the semiconductor light-emitting element according to each of the aforementioned embodiments. For example, semiconductor light-emitting element 1a according to Variation 1 of Embodiment 1 may include: a substrate including a GaN substrate; an n-type clad layer having a thickness of 1.5 μm and including Al_{0.25}Ga_{0.75}N (Si concentration: 1×10¹⁸ cm⁻³); an n-side first barrier layer having a thickness of 30 nm and including Al_{0.2}Ga_{0.8}N; a well layer having a thickness of 2.8 nm and including Al_{0.01}Ga_{0.98}In_{0.01}N; a p-side barrier layer having a thickness of 7 nm and including Al_{0.40}Ga_{0.515}In_{0.085}N; a p-side guide layer having a thickness of 30 nm and including Al_{0.2}Ga_{0.8}N; and a p-type clad layer having a thickness of 0.6 μm and including Al_{0.3}Ga_{0.7}N (Mg concentration: 1×10¹⁹ cm⁻³). Accordingly, it is possible to achieve a nitride-based semiconductor light-emitting element capable of producing ultraviolet laser light having an oscillation wavelength in a 360-nm band, and of controlling electron overflow from the well layer while suppressing an operating voltage.

Moreover, when at least one of p-side intermediate layer 14e, p-side barrier layer 14f, or p-side guide layer 14g is doped with p-type impurities, a conduction band potential energy of the at least one layer increases. As a result, it is possible to enhance an effect of controlling the electron overflow at the time of high-temperature high-power operation. Furthermore, in this case, since an electrical resistance of the layer doped with the p-type impurities decreases, it is possible to decrease the number of series resistance components included in the semiconductor light-emitting element. Concomitantly, since it is possible to suppress the occurrence of Joule heating during operation, it is possible to further increase optical output thermally saturated when the semiconductor light-emitting element performs high-temperature operation. C (carbon atoms) or Mg that does not easily diffuse from a position in which doping is performed may be used as the p-type impurities.

Here, for the AlGaInAs-based material including AlGaAs, a doping concentration may be at least 1×10¹⁷ cm⁻³ or at least 2×10¹⁷ cm⁻³ in order to increase electrical conductivity and a conduction band potential energy. Moreover, an excessive increase in doping concentration of impurities to p-side intermediate layer 14e, p-side barrier layer 14f, and p-side guide layer 14g close to well layer 14d causes an increase in free carrier loss, which results in a decrease in luminous efficiency of the semiconductor light-emitting element. For this reason, the doping concentration for each of these layers may be at most 1×10¹⁸ cm⁻³ or at most 6×10¹⁷ cm⁻³.

For the AlGaInN-based material including AlGaN, when Mg is used as dopants, a doping concentration may be at least 1×10¹⁸ cm⁻³ or at least 2×10¹⁸ cm⁻³ in order to increase electrical conductivity and a conduction band potential energy. Moreover, an excessive increase in doping concentration of impurities to p-side intermediate layer 14e, p-side barrier layer 14f, and p-side guide layer 14g close to well layer 14d causes an increase in free carrier loss, which results in a decrease in luminous efficiency of the semiconductor light-emitting element. For this reason, the doping concentration for each of these layers may be at most 1×10¹⁹ cm⁻³ or at most 6×10¹⁸ cm⁻³.

When at least one of p-side intermediate layer 14e, p-side barrier layer 14f, or p-side guide layer 14g is doped, a doping concentration of p-type impurities on a side close to well layer 14d may be relatively decreased. Since this decreases an impurity concentration of an impurity doping region closest to well layer 14d that is an emission layer, it is possible to reduce a free carrier loss. Accordingly, it is possible to reduce a waveguide loss of laser light propagating through a waveguide.

The present disclosure includes not only forms obtained by making various modifications to each of the aforementioned embodiments that may be conceived by a person skilled in the art, but also forms achieved by combining the constituent elements and functions in the embodiment without departing from the essence of the present disclosure.

For example, the variations of Embodiment 1 may be combined with each other or may be combined with other embodiments. For example, the window mirror structure according to Variation 7 of Embodiment 1 may be applied to the other variations of Embodiment 1 and other embodiments. It should be noted that when a nitride-based semiconductor material is used, among AlN, GaN, and InN, InN has the largest lattice constant and the smallest band gap energy. In this case, when a desired band gap energy is obtained by using a layer including a quaternary-based semiconductor material including AlGaInN for a well layer and each barrier layer, the In content rate of the well layer including AlGaInN increases, which increases a compression strain of the well layer, compared to when a desired band gap energy is obtained by using InGaN or AlGaN for the well layer. Accordingly, as with the above-described case in which the layer including the AlGaInAs-based material is used for the well layer and each barrier layer, it is possible to easily form a window structure.

Moreover, the semiconductor light-emitting element manufacturing method according to Embodiment 4 is applicable to manufacturing of a semiconductor light-emitting element according to other embodiments and variations thereof. For example, a manufacturing method is applicable to manufacturing of the semiconductor light-emitting element according to Embodiment 1 and each of the variations thereof, the manufacturing method being obtained by (i) omitting the step of forming the n-side guide layer from the semiconductor light-emitting element manufacturing method according to Embodiment 4 and (ii) changing the configuration of each semiconductor layer. In addition, a manufacturing method is applicable to manufacturing of semiconductor light-emitting element 101 according to Embodiment 2, the manufacturing method being obtained by (i) adding a step of forming first strain control layer 15 and second strain control layer 16 to the semiconductor light-emitting element manufacturing method according to Embodiment 4 and (ii) changing the configuration of each semiconductor layer. Additionally, a manufacturing method is applicable to manufacturing of semiconductor light-emitting element 201 according to Embodiment 3, the manufacturing method being obtained by (i) omitting the step of forming the current confinement layer from the step of forming the p-type clad layer included in the semiconductor light-emitting element manufacturing method according to Embodiment 4, (ii) adding a step of forming a ridge portion in the p-type clad layer and the contact layer and a step of forming current blocking layer 20 to the semiconductor light-emitting element manufacturing method according to Embodiment 4, and (iii) changing the configuration of each semiconductor layer.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The semiconductor light-emitting elements according to the present disclosure are applicable to, for example, light sources for laser processing as high-power high-efficient light sources.

1. A semiconductor light-emitting element comprising:
a substrate;
an n-type clad layer above the substrate;
an active layer above the n-type clad layer; and
a p-type clad layer above the active layer,
wherein the active layer includes:
a well layer;
an n-side first barrier layer on an n-type clad layer side of the well layer; and
a p-side barrier layer on a p-type clad layer side of the well layer,
the p-side barrier layer comprises In,
the n-side first barrier layer has an In composition ratio lower than an In composition ratio of the p-side barrier layer, and
the n-side first barrier layer has a band gap energy smaller than a band gap energy of the p-side barrier layer.

2. The semiconductor light-emitting element according to claim 1,
wherein a composition of the n-side first barrier layer is represented by Al_{ybn1}Ga_{1-xbn1-ybn1}In_{xbn1}As,
a composition of the p-side barrier layer is represented by Al_{ybp1}Ga_{1-xbp1-ybp1}In_{xbp1}As, and
0≤ybn1≤1,0≤xbn1<1,0<ybp1<1,0<xbp1<1, and xbn1<xbp1 are satisfied.

3. The semiconductor light-emitting element according to claim 2,
wherein ybn1<ybp1 is further satisfied.

4. The semiconductor light-emitting element according to claim 2,
wherein 0.2≤ybn1≤0.4, ybp1≤xbp1+0.975ybn1+0.069, ybp1≥0.4xbp1+0.975ybn1+0.029, and xbp1≤0.15 are further satisfied.

5. The semiconductor light-emitting element according to claim 2, further comprising:
a p-side intermediate layer between the well layer and the p-side barrier layer,
wherein a composition of the p-side intermediate layer is represented by Al_{ykp1}Ga_{1-ykp1}As, and
ybp1≤xbp1+0.975ykp1+0.069, ybp1≤0.4xbp1+0.975ykp1+0.029, and 0.2≤ykp1≤0.4 are satisfied.

6. The semiconductor light-emitting element according to claim 2, further comprising:
an n-side second barrier layer between the n-side first barrier layer and the well layer,
wherein a composition of the n-side second barrier layer is represented by Al_{ybn2}Ga_{1-xbn2-ybn2}In_{xbn2}As, and
ybn2≥xbn2+ybn1, ybn2≤0.4xbn2+0.975ybn1+0.061, xbn2≤0.15, and 0.2≤ybn1≤0.35 are satisfied.

7. The semiconductor light-emitting element according to claim 6, further comprising:
an n-side third barrier layer between the well layer and the n-side second barrier layer,
a composition of the n-side third barrier layer is represented by Al_{ybn3}Ga_{1-ybn3}As, and
ybn2≤xbn2+ybn3, ybn2≤0.4xbn2+0.975ybn3+0.061, and 0.2≤ybn3≤0.35 are satisfied.

8. The semiconductor light-emitting element according to claim 2, further comprising:
a p-side guide layer between the p-side barrier layer and the p-type clad layer, the p-side guide layer having a refractive index higher than a refractive index of the p-type clad layer.

9. The semiconductor light-emitting element according to claim 8,
wherein a composition of the p-side guide layer is represented by Al_{ygp1}Ga_{1-ygp1}As, and
ybp1≤xbp1+0.975ygp1+0.069, ybp1≥0.4xbp1+0.975ygp1+0.029, and 0.2≤ygp1≤0.4 are satisfied.

10. The semiconductor light-emitting element according to claim 8,
wherein a composition of the p-side guide layer is represented by (Al_{ygp2}Ga_{1-ygp2})_{0.5}In_{0.5}P.

11. The semiconductor light-emitting element according to claim 1,
wherein a composition of the n-type clad layer is represented by Al_{yn1}Ga_{1-yn1}As,
a composition of the p-type clad layer is represented by Al_{yp1}Ga_{1-yp1}As, and
0<yn1<yp1<1 is satisfied.

12. The semiconductor light-emitting element according to claim 1,
wherein a composition of the n-type clad layer is represented by (Al_{yn2}Ga_{1-yn2})_{0.5}In_{0.5}P,
a composition of the p-type clad layer is represented by (Al_{yp2}Ga_{1-yp2})_{0.5}In_{0.5}P, and
0<yn2<yp2<1 is satisfied.

13. The semiconductor light-emitting element according to claim 1,
wherein a composition of the well layer is represented by Al_{yw}Ga_{1-xw-yw}In_{xw}As, and
0≤yw<1 and 0<xw<1 are satisfied.

14. The semiconductor light-emitting element according to claim 13,
wherein 0<yw<1 is further satisfied.

15. The semiconductor light-emitting element according to claim 1,
wherein the substrate is a GaAs substrate.

16. The semiconductor light-emitting element according to claim 1,
wherein the n-type clad layer, the active layer, and the p-type clad layer each comprise a nitride-based semiconductor material.

17. The semiconductor light-emitting element according to claim 1,
wherein the p-side barrier layer comprises Al, and the n-side first barrier layer has an Al composition ratio lower than an Al composition of the p-side barrier layer.

18. The semiconductor light-emitting element according to claim 1,
wherein the n-side first barrier layer has a thickness greater than a thickness of the p-side barrier layer.

19. The semiconductor light-emitting element according to claim 1,
wherein the n-type clad layer has a band gap energy smaller than a band gap energy of the p-type clad layer.

20. The semiconductor light-emitting element according to claim 1,
wherein a light-emitting end face portion of the active layer has a window mirror structure.

21. The semiconductor light-emitting element according to claim 20,
wherein a portion of the active layer that has the window mirror structure has a band gap energy larger than a band gap energy of a portion of the active layer that does not have the window mirror structure.

22. A method of manufacturing a semiconductor light-emitting element, the method comprising:
preparing a substrate;
forming an n-type clad layer above the substrate;
forming an active layer above the n-type clad layer;
forming a p-type clad layer above the active layer; and
forming a window mirror structure in the active layer,
wherein the active layer includes:
a well layer;
an n-side first barrier layer on an n-type clad layer side of the well layer; and
a p-side barrier layer on a p-type clad layer side of the well layer,
the p-side barrier layer comprises In,
the n-side first barrier layer has an In composition ratio lower than an In composition ratio of the p-side barrier layer,
the n-side first barrier layer has a band gap energy smaller than a band gap energy of the p-side barrier layer, and
in the forming of the window mirror structure, vacancies or impurities are diffused into the active layer.

23. A nitride-based semiconductor light-emitting element comprising:
a substrate;
an n-type clad layer above the substrate;
an active layer above the n-type clad layer; and
a p-type clad layer above the active layer,
wherein the active layer includes:
a well layer;
an n-side first barrier layer on an n-type clad layer side of the well layer; and
a p-side barrier layer on a p-type clad layer side of the well layer,
the p-side barrier layer comprises Al, and
the n-side first barrier layer has an Al composition ratio lower than an Al composition ratio of the p-side barrier layer,
the n-side first barrier layer has a band gap energy smaller than a band gap energy of the p-side barrier layer, and
the n-side first barrier layer has a thickness greater than a thickness of the p-side barrier layer.
